(19) United States
(12) Patent Application Publication
(10) Pub. No.: US 2013/0277734 A1
(43) Pub. Date: Oct. 24, 2013

(54) SEMICONDUCTOR DEVICE AND METHOD FOR MANUFACTURING SAME

(71) Applicants: Toshifumi NISHIGUCHI, Kanagawa-ken (JP); Keiko KAWAMURA, Kanagawa-ken (JP); Hideki OKUMURA, Kanagawa-ken (JP); Tatsuya NISHIWAKI, Hyogo-ken (JP)

(72) Inventors: Toshifumi NISHIGUCHI, Kanagawa-ken (JP); Keiko KAWAMURA, Kanagawa-ken (JP); Hideki OKUMURA, Kanagawa-ken (JP); Tatsuya NISHIWAKI, Hyogo-ken (JP)

(73) Assignee: Kabushiki Kaisha Toshiba, Tokyo (JP)

(21) Appl. No.: 13/601,593

(22) Filed: Aug. 31, 2012

(30) Foreign Application Priority Data
Apr. 24, 2012 (JP) 2012-099154

(51) Int. Cl. H01L 29/78; H01L 21/336

(52) U.S. Cl. 257/330; 438/270; 257/E29.262; 257/E21.41

(57) ABSTRACT

According to one embodiment, a semiconductor device includes a first semiconductor region; a second semiconductor region having a side face and a lower face, and the faces surrounded by the first semiconductor region; a third semiconductor region provided between the second semiconductor region and the first semiconductor region; a fourth semiconductor region being in contact with an outer side face of the first semiconductor region; a plurality of first electrodes being in contact with the second semiconductor region, the third semiconductor region, and the first semiconductor region via an insulating film; a plurality of pillar areas extending from the third semiconductor region toward the fourth semiconductor region, each of the plurality of pillar areas being provided between adjacent ones of the plurality of first electrodes. An impurity density of each of the pillar areas and an impurity density of the third semiconductor region is substantially the same.

### CROSS-REFERENCE TO RELATED APPLICATIONS

This application is based upon and claims the benefit of priority from the prior Japanese Patent Application No. 2012-099154, filed on Apr. 24, 2012; the entire contents of which are incorporated herein by reference.

### FILED

Embodiments described herein relate generally to a semiconductor device and a method for manufacturing the same.

### BACKGROUND

While high integration of metal oxide semiconductor field effect transistors (MOSFETs) used for switching advances, high withstand voltage and low on-resistance are required for the MOSFEETs. In recent years, in order to respond to such requests, MOSFETs having a three-dimensional (3D) structure have attracted attention. In addition, in recent years, MOSFETs having a super junction structure, in which a resurf layer is formed within a drift layer, has attracted attention in the MOSFETs having such a 3D structure.

However, the manufacturing process of the 3D structure MOSFETs having the super junction structure is complicated. And a manufacturing method in which the number of processes can be decreased and a structure of the semiconductor device for realizing the manufacturing method are required.

### BRIEF DESCRIPTION OF THE DRAWINGS

FIG. 1 is a schematic perspective view of a semiconductor device according to a first embodiment;

FIGS. 2A and 2B are schematic views of the semiconductor device according to the first embodiment;

FIGS. 3A to 8B are schematic cross-sectional views and schematic top views illustrating processes of manufacturing the semiconductor device according to the first embodiment;

FIGS. 9A and 9B are schematic top views illustrating processes of manufacturing a semiconductor device according to a reference example;

FIG. 10 is a schematic perspective view of a semiconductor device according to a second embodiment;

FIG. 11A is a schematic cross-sectional view of the semiconductor device according to the second embodiment;

FIG. 11B is a schematic top view of the semiconductor device according to the second embodiment;

FIGS. 12A to 16B are schematic cross-sectional views and schematic top views illustrating processes of manufacturing the semiconductor device according to the second embodiment;

FIGS. 17A and 17B are schematic cross-sectional views and schematic top views of a semiconductor device according to a third embodiment;

FIGS. 18A to 19B are schematic cross-sectional views and schematic top views illustrating processes of manufacturing the semiconductor device according to the third embodiment;

FIGS. 20A and 20B are schematic cross-sectional views and schematic top views of a semiconductor device according to a fourth embodiment;

FIGS. 21A to 22B are schematic cross-sectional views and schematic top views illustrating processes of manufacturing the semiconductor device according to the fourth embodiment;

FIG. 23 is a schematic top view of a semiconductor device according to a fifth embodiment;

FIGS. 24A and 24B are schematic cross-sectional views and schematic top views of a semiconductor device according to a first example of a sixth embodiment;

FIGS. 25A and 25B are schematic cross-sectional views and schematic top views of a semiconductor device according to a second example of the sixth embodiment;

FIG. 26 is a schematic top view of a semiconductor device according to a seventh embodiment; and

FIGS. 27A to 33B are schematic cross-sectional views and schematic top views illustrating processes of manufacturing a semiconductor device according to an eighth embodiment.

### DETAILED DESCRIPTION

In general, according to one embodiment, a semiconductor device includes a first semiconductor region of a first conductivity type. The device includes a second semiconductor region of the first conductivity type having a side face and a lower face, and the side face and the lower face surrounded by the first semiconductor region. The device includes a third semiconductor region of a second conductivity type provided between the second semiconductor region and the first semiconductor region. The device includes a fourth semiconductor region of the first conductivity type being in contact with an outer side face of the first semiconductor region, the outer side face opposite to an inner side face of the first semiconductor region, and the inner side face being in contact with the third semiconductor region. The device includes a plurality of first electrodes being in contact with the second semiconductor region, the third semiconductor region, and the first semiconductor region via an insulating film. The device includes a plurality of pillar areas of the second conductivity type extending from the third semiconductor region toward the fourth semiconductor region, each of the plurality of pillar areas being provided between adjacent ones of the plurality of first electrodes, and extending in a direction parallel to an upper face of the first semiconductor region. The device includes a second electrode electrically connected to the second semiconductor region and the third semiconductor region. The device includes a third electrode electrically connected to the fourth semiconductor region. And an impurity density of each of the pillar areas and an impurity density of the third semiconductor region is substantially the same.

Hereinafter, embodiments will be described with reference to the drawings. In the description below, like reference numerals in the drawings denote like elements, and thus overlapping description of elements will be omitted.

### First Embodiment

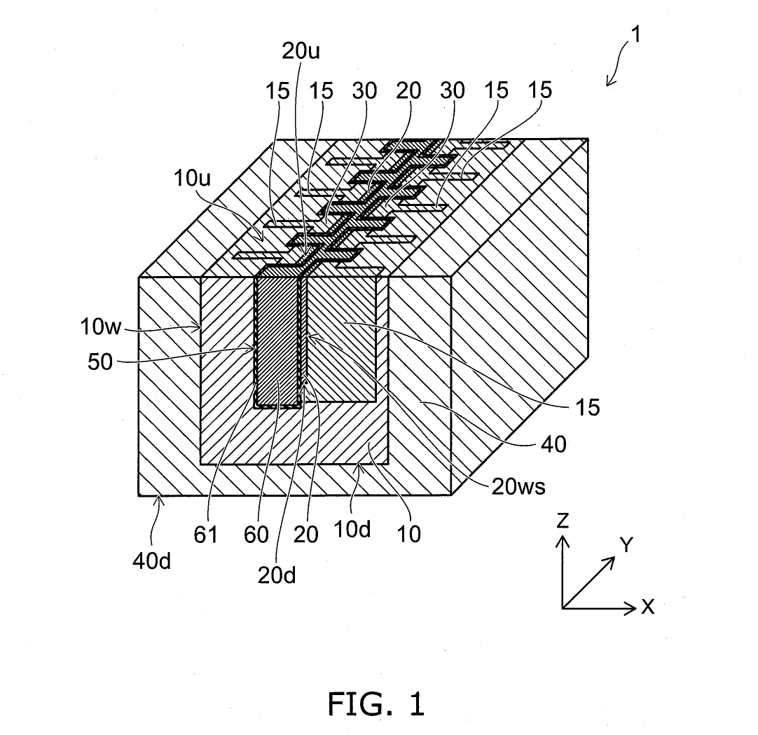

FIG. 1 is a schematic perspective view of a semiconductor device according to a first embodiment.

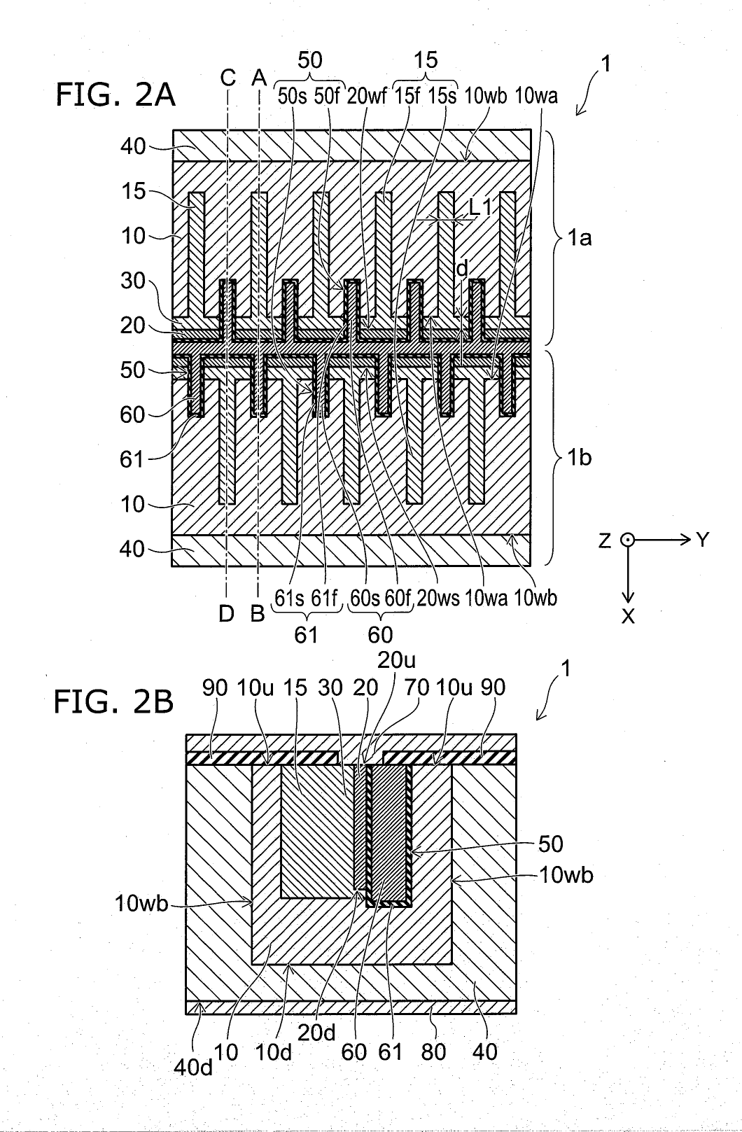

FIGS. 2A and 2B are schematic views of the semiconductor device according to the first embodiment. FIG. 2A is a schematic top view of the semiconductor device of the first embodiment, and FIG. 2B is a schematic cross-sectional view along line A-B illustrated in FIG. 2A.

The front face of the semiconductor device 1 illustrated in FIG. 1 corresponds to a cross-section at a position along line C-D illustrated in FIG. 2A. In FIGS. 1 and 2A, in order to represent the internal structure of the semiconductor device 1, source and drain electrodes are not illustrated.

The semiconductor device 1 of the first embodiment is a MOSFET having a three-dimensional (3D) structure.

The semiconductor device 1 includes a first-conductivity type (for example, n type) drift region 10 (first semiconductor region) and a first-conductivity type source region 20 (second semiconductor region). The source region 20 includes side faces (a first side face 20ws and a second side face 20ws) and a lower face 20d. The source region 20 is formed such that the side faces 20wf and 20ws of the source region 20 and the lower face 20d of the source region 20 are surrounded by the drift region 10. In other words, the source region 20 extends from the upper face 10u side of the drift region 10 toward the lower face 10d side, which is positioned on an opposite side of the upper face 10u, of the drift region 10. In the figure, a direction from the upper face 10u of the drift region 10 toward the lower face 10d side of the drift region 10 is set as direction Z.

In addition, the semiconductor device 1 includes a second-conductivity type (for example, p type) base region 30 (third semiconductor region) provided between the source region 20 and the drift region 10, and a first-conductivity type drain region 40 (fourth semiconductor region). The drain region 40 is in contact with the outer side face 10wb, which is positioned on an opposite side of the inner side face 10wa of the drift region 10, of the drift region 10. The inner side face 10wa of the drift region 10 is in contact with the base region 30. The base region 30 and the drift region 10 are interposed between the drain region 40 and the source region 20, and the drain region 40 is provided on an opposite side of the source region 20. The drain region 40 is in contact with the lower face 10d of the drift region 10 in addition to being in contact with the outer side face 10wb of the drift region 10.

Furthermore, the semiconductor device 1 includes a plurality of gate electrodes 60 (first electrodes). Each of the plurality of gate electrodes 60 is in contact with the source region 20, the base region 30, and the drift region 10 via a gate insulating film 61. The gate electrodes 60 are provided in a plurality of trenches 50 via the gate insulating film 61. Each of the plurality of trenches 50 passes through the base region 30 from the source region 20 so as to reach the drift region 10. In addition, each of the plurality of trenches 50 extends from the upper face of the source region 20, the upper face of the base region 30, and the upper face 10u of the drift region 10 to the lower face 40d side of the drain region 40. The depth of each of the plurality of trenches 50 is in the range of 10 to 30 μm (micrometers).

Here, the gate electrode 60 includes a first gate electrode 60f (a first portion of gate electrode 60) and a second gate electrode 60s (a second portion of gate electrode 60). The second gate electrode 60s extends in a direction opposite to a direction in which the first gate electrode 60f extends (see FIG. 2A). For example, the first gate electrodes 60f are provided in a plurality of first trenches 50f via a first gate insulating film 61f. The first gate electrodes 60f pass through the base region 30, which is in contact with the first side face 20wf of the source region 20, from the source region 20. And the first gate electrodes 60f extend up to the drift region 10 that is further in contact with the base region 30. In other words, a plurality of the first gate electrodes 60f extend from the source region 20 up to the drift region 10 via the base region 30. The drift region 10 is in contact with the base region 30. The base region 30 is in contact with the first side face 20wf of the source region 20. In addition, the second gate electrodes 60s are provided in a plurality of second trenches 50s via a second gate insulating film 61s. The second gate electrodes 60s pass through the base region 30, which is in contact with the second side face 20ws of the source region 20, from the source region 20. And the second gate electrodes 60s extend up to the drift region 10 that is further in contact with the base region 30. The second side face 20ws is opposite to the first side face 20wf. In other words, a plurality of the second gate electrodes 60s extends from the source region 20 up to the drift region 10 via the base region 30. The drift region 10 is in contact with the base region 30. The base region 30 is in contact with the second side face 20ws of the source region 20. The second side face 20ws is positioned on an opposite side of the first side face 20wf of the source region 20.

In addition, the semiconductor device 1 includes second-conductivity type pillar areas 15. Each of the pillar areas 15 extends from the base region 30 provided between adjacent ones of a plurality of gates 60 (or a plurality of trenches 50) toward the drain region 40. In other words, the semiconductor device 1 includes the plurality of pillar areas 15 and the plurality of gate electrodes 60 in the direction Y that is perpendicular to the X direction and the Z direction. The pillar area 15 may be referred to as a resurf region 15. The pillar area 15 extends in a direction that is approximately parallel to the upper face 10u of the drain region 40. In the figure, a direction in which the pillar area 15 extends from the base region 30 is set as the direction X. In a case where the base region 30 and the plurality of pillar areas 15 are viewed for the direction Z, the base region 30 and the plurality of pillar areas 15 form like a comb shape.

Here the pillar area 15 includes a first pillar area 15f of the second conductivity type and a second pillar area 15s of the second conductivity type. The second pillar area 15s extends in a direction opposite to the direction in which the first pillar area 15f extends (see FIG. 2A). The first pillar area 15f extends from the base region 30, which is provided between the plurality of first trenches 50f, toward the drift region 10 side on which the plurality of first trenches 50f extends. In other words, the first pillar area 15f extends from the base region 30 provided between adjacent ones of the plurality of the first gate electrodes 60f toward the drift region 10 side in which the plurality of the first gate electrodes 60f extends. The second pillar area 15s extends from the base region 30, which is provided between the plurality of second trenches 50s, toward the drift region 10 side on which the plurality of second trenches 50s extends. In other words, the second pillar area 15s extends from the base region 30 provided between adjacent ones of a plurality of the second gate electrodes 60s toward the drift region 10 side in which the plurality of the second gate electrodes 60s extends.

That is, the semiconductor device 1 has a super junction structure in which the drift region 10 of the first conductivity type and the pillar area 15 of the second conductivity type are alternately disposed in the direction Y. In addition, in FIG. 2A, in a case where an upper area from the center of the source region 20 is represented as area 1a, and a lower area from the center of the source region 20 is represented as area 1b, there is an approximate phase shifting of 180° between the phases of areas 1a and 1b in the direction Y in which the gate electrodes 60 are arranged. In addition, there is an approximate phase shifting of 180° between the phases of areas 1a and 1b in the direction Y in which the pillar areas 15 are arranged.

For example, the plurality of the first gate electrodes 60f (or the plurality of first trenches 50f) and the plurality of the second gate electrodes 60s (or the plurality of second trenches 50s) are arranged in the direction (direction Y) in which the source region 20 extends. In a case where the semiconductor device 1 is viewed for a direction (direction Z) perpendicular to the upper face 10u of the drift region 10, there is phase shifting between a phase in which the plurality of the first gate electrodes 60f (or the plurality of first trenches 50f) is arranged and a phase in which the plurality of the second gate electrodes 60s (or the plurality of second trenches 50s) is arranged. That is, the phases of two are out of phase. The value of phase shifting is about 180°.

In addition, in a case where the semiconductor device 1 is viewed for a direction (direction Z) perpendicular to the upper face 10u of the drift region 10, there is phase shifting between a phase in which a plurality of the first pillar areas 15f provided between the plurality of the first gate electrodes 60f (or the plurality of first trenches 50f) is arranged and a phase in which a plurality of the second pillar areas 15s provided between the plurality of the second gate electrodes 60s (or the plurality of second trenches 50s) is arranged. The value of phase shifting is about 180°.

Furthermore, when the semiconductor device 1 is viewed for a direction (direction Z) perpendicular to the upper face 10u of the drift region 10, the width of the pillar area 15 in the direction Y is narrower than that of the drift region 10 interposed between the pillar areas 15 in the Y direction. In addition, the thickness d (the thickness of the base region 30 in the direction X) of the base region 30 interposed between the source region 20 and the drift region 10 and the width L1 of the pillar area 15 in a direction (direction Y) that is approximately perpendicular to the extending direction (direction X) of the pillar area 15 from the base region 30 to the drift region 10 side satisfy the relation of L1≦2d. For example, the width L1 is in the range of 1.0 to 1.5 μm.

In addition, the semiconductor device 1 includes a source electrode 70 (second electrode) that is electrically connected to the source region 20 and the base region 30, and a drain electrode 80 (third electrode) that is electrically connected to the drain region. An insulating layer 90 is interposed between the source electrode 70 and the drain region 40, and between the source electrode 70 and the drift region 10.

The main component of each of the drain region 40, the drift region 10, the source region 20, the base region 30, and the pillar area 15, for example, is silicon (Si). Examples of the impurity element of the first conductivity type (for example, the n type) include phosphorus (P), arsenic (As), and the like. In addition, examples of the impurity element of the second conductivity (for example, the p type) include boron (B) and the like. The main component of each of the source electrode 70 and the drain electrode 80, for example, is tungsten (W) or the like. The main component of the gate electrode 60, for example, is polysilicon (polycrystalline silicon). An example of the material of each of the gate insulating film 61 and the insulating layer 90 is silicon oxide (e.g. SiO₂).

The density of the impurity elements of the first conductivity type that are contained in the drift region 10 is lower than the density of the impurity elements of the first conductivity type that are contained in the drain region 40. The density of the impurity elements of the first conductivity type that are contained in the drift region 10, for example, is in the range of 1/10¹⁶ to 1/10¹⁷ (atoms/cm³). The density of the impurity elements of the first conductivity type that are contained in the drain region 40 is 1/10¹⁹ (atoms/cm³) or more.

The density of the impurity elements of the second conductivity type that are contained in each of the pillar areas 15 and the density of the impurity elements of the second conductivity type that are contained in the base region 30 are substantially the same. For example, a difference between the density of the impurity elements of the second conductivity type that are contained in the pillar area 15 and the density of the impurity elements of the second conductivity type that are contained in the base region 30 is 5×10¹⁷ or less. The density of the impurity elements that are contained in the pillar area 15 (or the density of the impurity elements that are contained in the base region 30) for example, is in the range of 5×10¹⁷ to 10¹⁸ (atoms/cm³).

The density of the impurity elements of the first conductivity type that are contained in the drift region 10 and the density of the impurity elements of the second conductivity type that are contained in the pillar area 15 are adjusted such that the drift region 10 and the pillar area 15 are completely depleted when the semiconductor device 1 is turned off.

Here, the density (unit: atoms/cm³) of the impurity elements of the first conductivity type or the second conductivity type that are contained in a semiconductor layer is defined as a value that is acquired by dividing a total number of the impurity elements of the first conductivity type or the second conductivity type by the volume of the semiconductor layer.

In a case where impurity elements of the first conductivity type and impurity elements of the second conductivity type are contained in a semiconductor layer, the impurity density of the impurity elements contained in the semiconductor layer is defined as below.

For example, in a case where a total number of the impurity elements of the first conductivity type is greater than a total number of the impurity elements of the second conductivity type within the semiconductor layer, the impurity density of the impurity elements within the semiconductor layer is defined as a value that is acquired by dividing a value, which is acquired by subtracting the total number of the impurity elements of the second conductivity type from the total number of the impurity elements of the first conductivity type, by the volume of the semiconductor layer. On the other hand, in a case where the total number of the impurity elements of the second conductivity type is greater than the total number of the impurity elements of the first conductivity type within the semiconductor layer, the impurity density of the impurity elements within the semiconductor layer is defined as a value that is acquired by dividing a value, which is acquired by subtracting the total number of the impurity elements of the first conductivity type from the total number of the impurity elements of the second conductivity type, by the volume of the semiconductor layer.

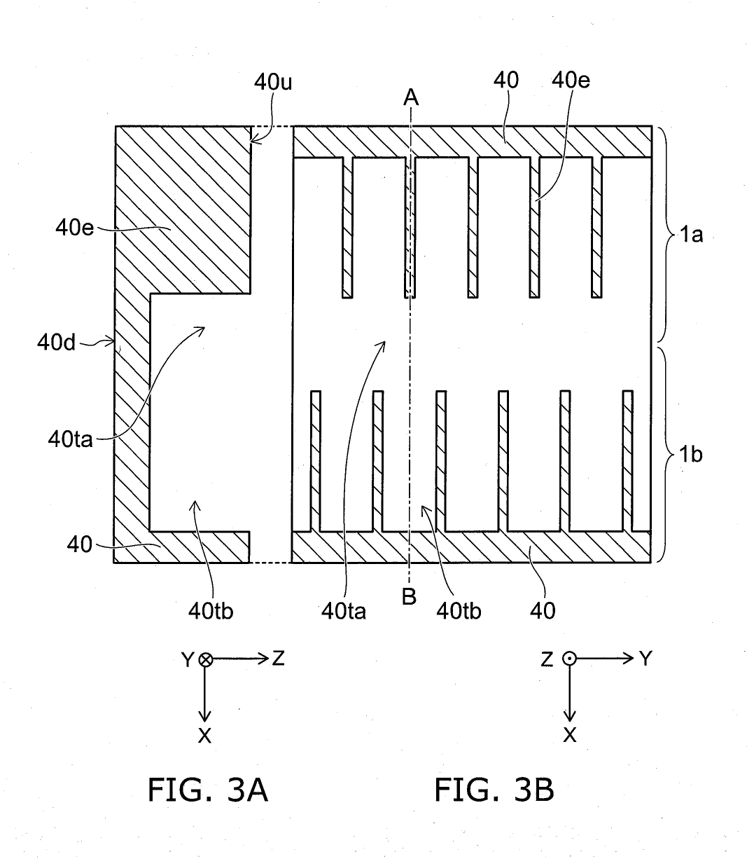

FIGS. 3A to 8B are schematic cross-sectional views and schematic top views illustrating processes of manufacturing the semiconductor device according to the first embodiment. FIGS. 3A, 4A, 5A, 6A, 7A, and 8A are schematic cross-sectional views along lines A-B illustrated in FIGS. 3B, 4B, 5B, 6B, 7B, and 8B as schematic top views.

First, after a drain region 40 is prepared previously, as illustrated in FIGS. 3A and 3B, a trench 40ta (fifth trench), which extends in a direction approximately parallel to the upper face 40u of the drain region 40, is formed inside the drain region 40 by using a lithographic method and a reactive ion etching (RIE) method. In addition, a plurality of trenches 40tb (sixth trenches), which extend in a direction (direction X) approximately vertical to a direction (direction Y), is formed by using a lithographic method and a reactive ion etching method. The plurality of trenches 40tb are connected to the trench 40ta, and extend in the direction approximately vertical to the direction in which the trench 40ta extends and a depth direction (Z direction) of the trench 40ta. Here, the drain region 40 is a Si crystal substrate that contains impurity elements of the first conductivity type. The plane direction of the upper face 40u (or the lower face 40d) of the drain region 40, for example, is a Si (100) plane or a Si (110) plane.

In other words, by providing the trenches 40ta and 40tb in a drain region 40, the drain region 40 includes a plurality of extending portions 40e that extend in the direction X. Here, in FIGS. 3A and 3B, in a case where an upper area from the center of the trench 40ta is represented by area 1a and a lower area from the center of the trench 40ta is represented by area 1b, the phase of extending portion 40e is 180° out-of-phase with areas 1a and 1b in the direction Y.

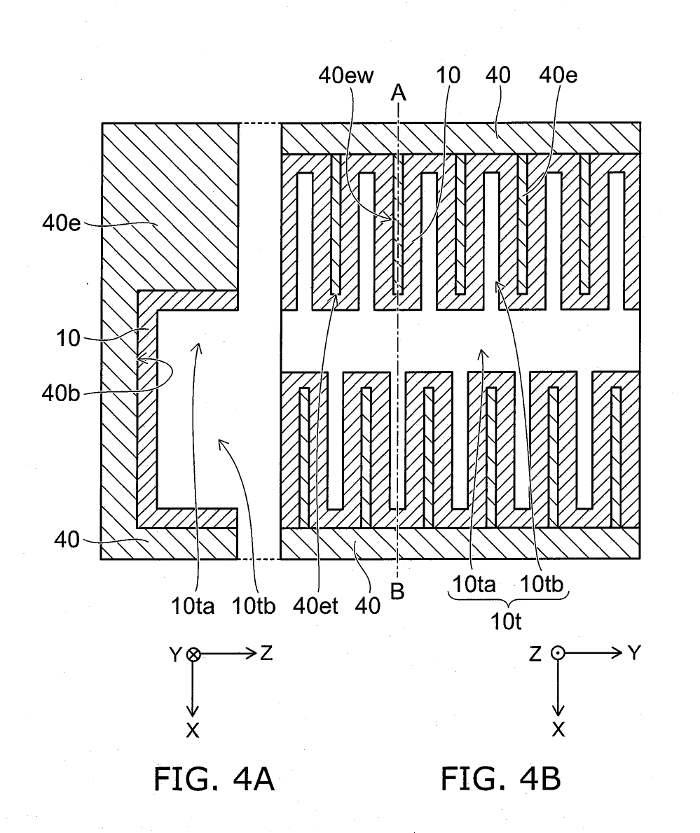

Next, a drift region 10, which has an impurity density lower than the drain region 40, is formed using an epitaxial growth method inside the plurality of trenches 40tb and inside the trench 40ta. Here, the drift region 10 is conditioned so as not to be completely embedded inside the trench 40ta and inside the plurality of trenches 40tb. The state is illustrated in FIGS. 4A and 4B.

As illustrated in FIGS. 4A and 4B, a side face 40ew of the extending portion 40e, an end face 40et of the extending portion 40e, and a bottom face 40b of the drain region 40 are covered with the drift region 10.

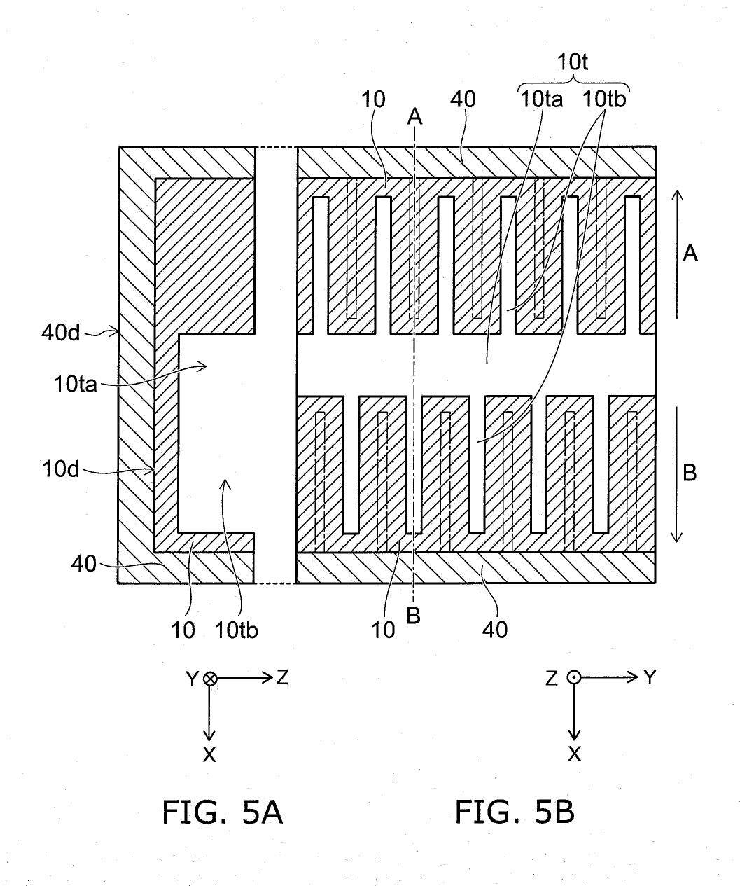

Next, an annealing process is performed for the drain region 40 and the drift region 10. With such an annealing process, impurity elements that are contained in the extending portion 40e diffuse into the drift region 10 that is in contact with the extending portion 40e. In other words, the impurity density of the extending portion 40e decreases from the impurity density immediately after formation of the trenches 40ta and 40tb, and the impurity density of the drift region 10 increase from the impurity density immediately after formation of the drift region 10 inside the trenches 40ta and 40tb. The state is illustrated in FIGS. 5A and 5B.

In addition, the widths of the trenches 40ta and 40tb described above decrease, a trench 10ta (third trench) and a plurality of trenches 10tb are formed. The trench 10ta (third trench) extends in a direction (direction Y) that is approximately parallel to the upper face 10u of the drift region 10. And the plurality of trenches 10tb (fourth trenches) extend in a direction (direction X) that is approximately perpendicular to the extending direction (direction Y) of the trench 10ta and the depth direction (direction Z) of the trench 10ta. In other words, the trench 10ta as a trunk and the trenches 10tb as branches from the trench 10ta are formed inside the drift region 10 that is provided on the drain region 40. In addition, the trench 10ta and a plurality of the trenches 10tb are collectively referred to as trenches 10t.

The plurality of the trenches 10tb are connected to the trench 10ta. In addition, the width of the trench 10tb in the direction Y is smaller than the width of the trench 10ta in the direction X.

Here, when the drift region 10 is viewed for a direction (direction Z) that is perpendicular to the upper face 10u of the drift region 10, the plurality of the trenches 10tb extend in a second direction (direction A in the figure) and a third direction (direction B in the figure). The second direction (direction A in the figure) is approximately perpendicular to a first direction (direction Y in the figure) in which the trench 10ta extends. And a third direction (direction B in the figure) is approximately perpendicular to the direction Y and is opposite to the second direction. In addition, there is phase shifting between the phase in which a plurality of the trenches 10tb extending in the second direction are arranged in the first direction and the phase in which a plurality of the trenches 10tb extending in the third direction are arranged in the first direction. The value of phase shifting is about 180°.

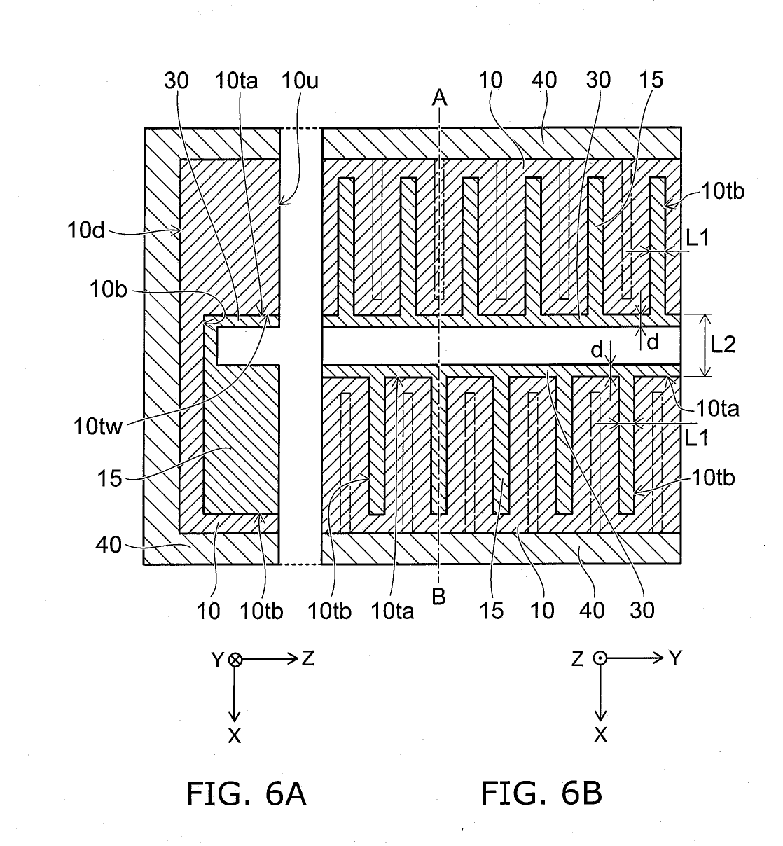

Next, as illustrated in FIGS. 6A and 6B, pillar areas 15 are formed inside the plurality of the trenches 10tb, and base regions 30 are formed on the inner side face 10tw of the trench 10ta and the bottom face 10b of the trench 10ta, by using an epitaxial growth method. Here, while forming the pillar areas 15 and the base regions 30, impurity elements of the second conductivity type are introduced into the pillar areas 15 and the base regions 30. The trench 10ta is conditioned such that the base region 30 may not be completely embedded in the trench 10ta.

In the first embodiment, when viewed for a direction (direction Z) that is perpendicular to the upper face 10u of the drift region 10, the width L1 of each of the plurality of the trenches 10tb in a direction that is approximately perpendicular to the extending direction of the plurality of the trenches 10tb is adjusted so as to satisfy the following relation with respect to the thickness d of the base region 30 that is interposed between the source region 20 and the drift region 10.

L1≦2×d Expression (1)

In addition, when viewed for the direction (direction. Z) that is perpendicular to the upper face 10u of the drift region 10, the width L2 of the trench 10ta in a direction that is approximately perpendicular to the extending direction of the trench 10ta, the width L1 of each of the plurality of the trenches 10tb in a direction that is approximately perpendicular to the extending direction of the plurality of the trenches 10tb, and the thickness d of the base region 30 that is interposed between the source region 20 and the drift region 10 are adjusted so as to satisfy the following relation.

d≦L1<L2 Expression (2)

By designing the relation between the width L1 and the thickness d so as to satisfy Expression (1), the inside of the trench 10tb is completely embedded by the pillar area 15. In addition, by designing the relation between the width L1 and the width L2 so as to satisfy Expression (2), the inside of the trench 10ta is not completed embedded by the base region 30.

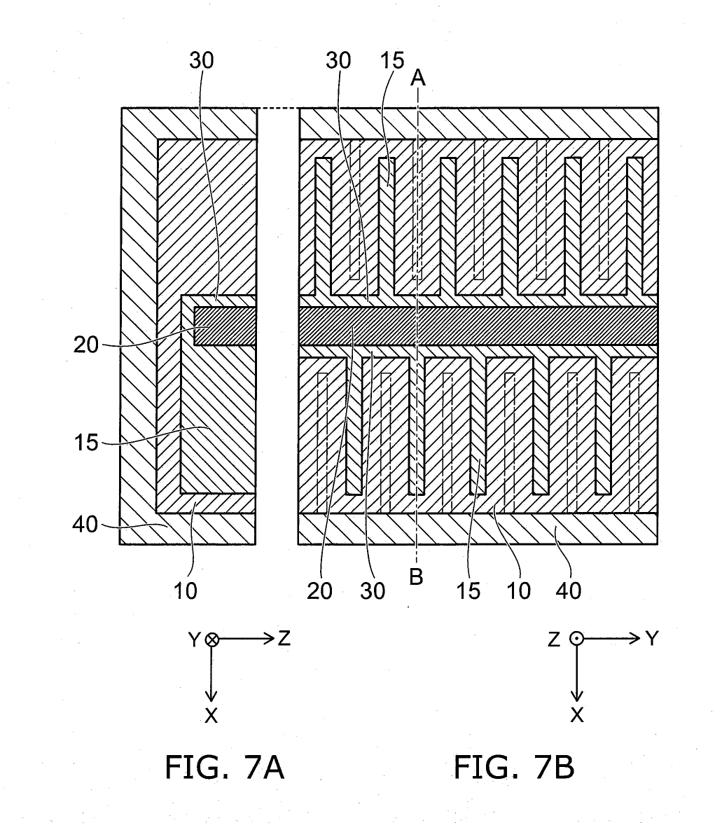

Next, as illustrated in FIGS. 7A and 7B, a source region 20 having side faces 20wf and 20ws and the bottom face 20d surrounded by the base region 30 is formed by using an epitaxial growth method. While forming the source region 20, impurity elements of the first conductivity type are introduced into the source region 20. Next, as necessary, a chemical mechanical polishing (CMP) process is performed for the upper face of the drain region 40, the upper face of the drift region 10, the upper face of the base region 30, and the upper face of the source region 20 such that the upper face of the drain region 40, the upper face of the drift region 10, the upper face of the base region 30, and the upper face of the source region 20 are formed as one face.

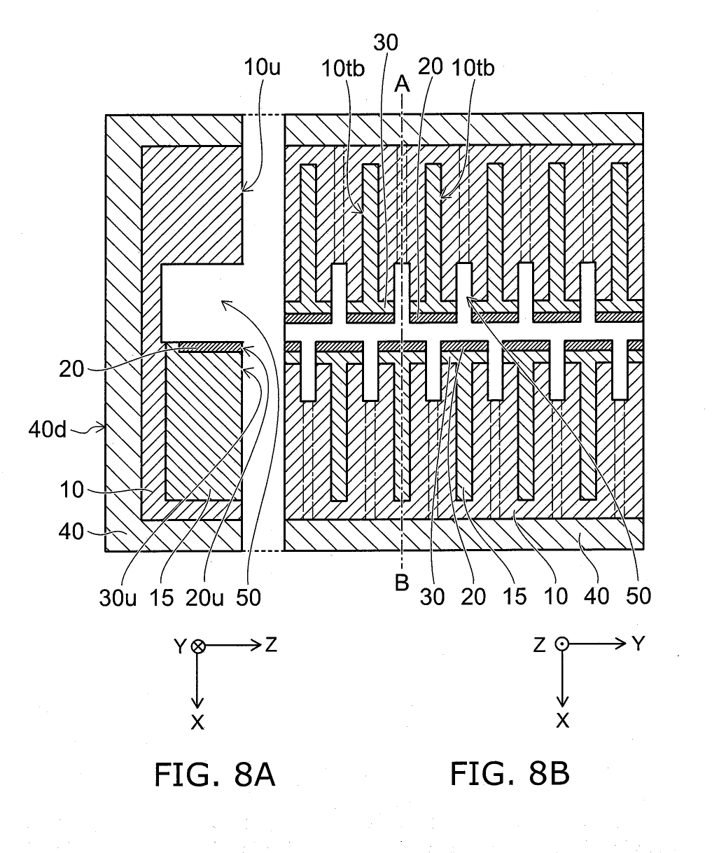

Next, as illustrated in FIGS. 8A and 8B, trenches 50 (fifth trenches) are formed by using the RIE. The trenches 50 pass through the base region 30 from the source region 20 that is provided between the plurality of trenches 10tb and reach the drift region 10. And the trenches 50 extend from the upper face 20u of the source region 20, the upper face 30u of the base region 30, and the upper face 10u of the drift region 10 toward the lower face 40d side of the drain region 40.

Thereafter, as illustrated in FIGS. 1, 2A, and 2B, a gate insulating film 61 is formed inside the trench 50, and a gate electrode 60 is formed further inside the trench 50 via the gate insulating film 61. The gate insulating film 61, for example, is formed by using a chemical vapor deposition (CVD) method, a thermal oxidation method under the atmosphere of at least one of hydrogen and oxygen, or the like. The gate electrode 60, for example, is formed by the CVD method. In addition, a source electrode 70 that is connected to the source region 20 and the base region 30 and a drain electrode 80 that is connected to the drain region 40 are formed. The semiconductor device 1 is formed by such a manufacturing process.

The semiconductor device 1 of the first embodiment introduces the pillar area 15 to the drift region 10 so as to have a so-called super junction structure. Accordingly, compared to a MOSFET having a three dimensional structure in which the super junction structure is not included, the depletion of the drift region 10 and the pillar area 15 is promoted when the semiconductor device 1 is in the off-state. As a result, the breakdown voltage of the semiconductor device 1 is improved, compared to a MOSFET having a three-dimensional structure in which the super junction structure is not included.

In addition, by introducing the super junction structure, the impurity density of the drift region 10 can increase, compared to a MOSFET having a three-dimensional structure in which the super junction structure is not included. As a result, the resistivity of the drift region 10 further decreases, and the on-resistance of the MOSFET decreases. In addition, when a depletion layer is regarded as an insulating layer, it is easy for the depletion layer to grow inside the drift region 10 in the semiconductor device 1, and accordingly, the gate-to-drain capacitance decreases. Therefore, the feedback capacitance (Crss) of the MOSFET decreases.

In addition, in the semiconductor device 1, the width of the pillar area 15 in the direction Y is narrower than that of the drift region 10 that is interposed between the pillar areas 15 in the direction Y. Accordingly, the width of the drift region 10 interposed between the pillar areas 15 is larger than the width of a case where the width of the pillar area 15 and the width of the drift region 10 interposed between the pillar areas 15 are the same. As a result, the on-resistance of the semiconductor device 1 further decreases.

As a manufacturing method other than that of the first embodiment, there is a method in which, instead of simultaneously forming the pillar areas 15 and the base region 30, pillar areas 15 are formed after the gate electrodes 60 are formed. According to the method, after gate electrodes 60 are formed inside trenches 50 via the gate insulating film 61 in the state illustrated in FIGS. 8A and 8B, the pillar areas 15 are formed between a plurality of the gate electrodes 60.

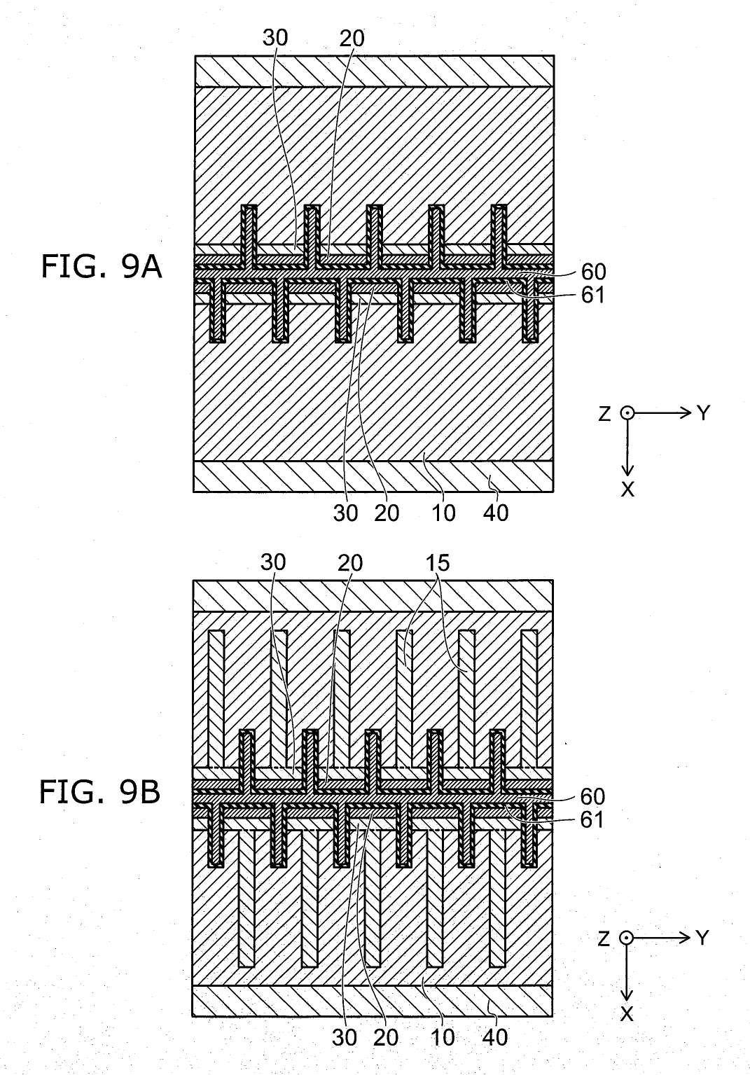

FIGS. 9A and 9B are schematic top views illustrating processes of manufacturing a semiconductor device according to a reference example.

For example, as illustrated in FIG. 9A, instead of forming the pillar areas 15 simultaneously with the base region 30, after base regions 30 and source regions 20 are formed, trenches 50 are formed, and gate electrodes 60 are formed inside the trenches 50 via the gate insulating film 61.

Next, as illustrated in FIG. 9B, pillar areas 15 are formed between a plurality of the gate electrodes 60. In other words, the pillar areas 15 are formed following the formation of gate trenches.

However, according to the method, after the plurality of gate electrodes 60 is formed, a dedicated process to form the pillar areas 15 between the plurality of gate electrodes 60 is necessary. In addition, in order to form the pillar areas 15 between the plurality of gate electrodes 60, the position alignment of the pillar areas 15 is necessary. It is difficult more and more to perform the position alignment as the narrowing in the pitch of the trench gates advances. In addition, in a case where the base region 30 and the pillar areas 15 are formed by separate processes, there is also a disadvantage that the number of manufacturing processes does not decrease.

In contrast, in the process of manufacturing the semiconductor device 1, after the trenches 10t (trenches 10ta and 10tb) are formed, the base region 30 and the pillar area 15 are simultaneously formed. Accordingly, the number of manufacturing processes is smaller than that of a case where the base region 30 and the pillar areas 15 are formed by separate processes. In addition, in the process of manufacturing the semiconductor device 1, the position alignment for forming the pillar areas 15 between the plurality of gate electrodes 60 is not necessary. In other words, in the process of manufacturing the semiconductor device 1, the pillar areas 15 can be formed in a self-aligned manner even in a case where the narrowing in the pitch of the trench gate advances. In other words, the pillar areas 15 can be formed with high accuracy even in a case where the narrowing in the pitch of the trench gate advances.

In addition, in the first embodiment, since there is phase shifting between the phase in which a plurality of the trenches 10tb extending in the second direction is arranged in the first direction and the phase in which a plurality of the trenches 10tb extending in the third direction is arranged in the first direction, the connection portion of the trench 10tb and the trench 10ta forms a “T”-shaped path. Accordingly, when epitaxial growth is performed, the supply of raw material gas to the inside of the trenches is suppressed more than in a case where the connection portion of the trenches 10tb and 10ta forms a cross-shaped path. Thereby a less supply shortage of the raw material gas occurs at the time of the epitaxial growth. Accordingly, it is difficult for a crack to occur in an epitaxial growth layer (for example, the base region 30 and the source region 20).

### Second Embodiment

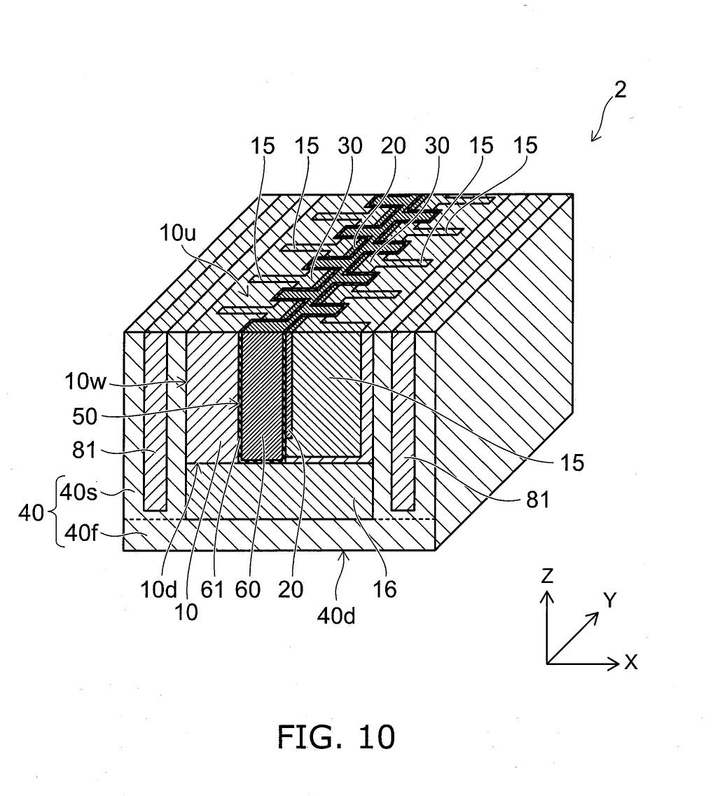

FIG. 10 is a schematic perspective view of a semiconductor device according to a second embodiment.

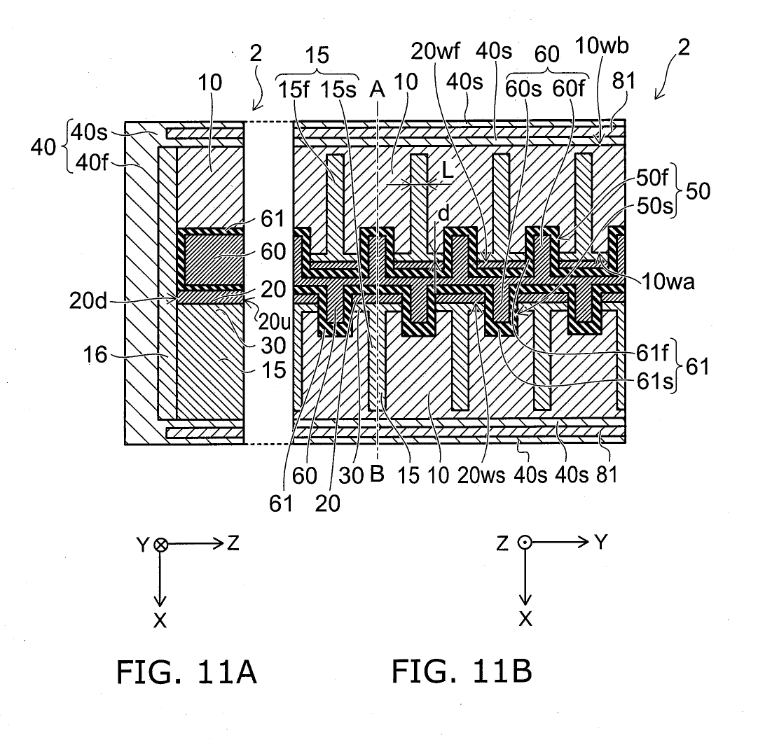

FIG. 11A is a schematic cross-sectional view of the semiconductor device according to the second embodiment, and FIG. 11B is a schematic top view of the semiconductor device according to the second embodiment. FIG. 11A is a schematic cross-sectional view along line A-B illustrated in FIG. 11B.

In FIGS. 10, 11A, and 11B, in order to represent the internal structure of the semiconductor device 2, a source electrode is not illustrated.

The semiconductor device 2 of the second embodiment is a MOSFET having a three-dimensional structure. The basic structure of the semiconductor device 2 is the same as the basic structure of the semiconductor device 1. However, the semiconductor device 2 further includes a semiconductor region 16 (fifth semiconductor region) and a drain electrode 81.

The semiconductor device 2 includes a first-conductivity type (for example, the n type) drift region 10 and a first-conductivity type source region 20. The source region 20 includes side faces (a first side face 20ws and a second side face 20ws) and a lower face 20d. The source region 20 is formed such that the side faces 20wf and 20ws of the source region 20 and the lower face 10d of the source region 20 are surrounded by the drift region 10.

In addition, the semiconductor device 2 further includes a semiconductor region 16 of the first conductivity type between the lower face 10d of the drift region 10 and the drift region 10.

Furthermore, the semiconductor device 2 includes a second conductivity-type (for example, the p type) base region 30 provided between the source region 20 and the drift region 10, and a first-conductivity type drain region 40. The drain region 40 is in contact with the outer side face 10wb of the drift region 10 that is positioned on an opposite side of the inner side face 10wa of the drift region 10 that is in contact with the base region 30. The base region 30 and the drift region 10 are interposed between the drain region 40 and the source region 20, and the drain region 40 is provided on an opposite side of the source region 20.

The drain region 40 is in contact with the lower face 10d of the drift region 10 in addition to being in contact with the outer side face 10wb of the drift region 10. Here, the drain region that is in contact with the lower face 10d of the drift region 10 is set as a first drain region 40f, and the drain region that is in contact with the outer side face 10wb of the drift region 10 is set as a second drain region 40s.

Furthermore, the semiconductor device 2 includes a gate electrode 60. The gate electrode 60 is in contact with the source region 20, the base region 30, and the drift region 10 via a gate insulating film 61. The gate electrode 60 is provided in a plurality of trenches 50 via the gate insulating film 61. Each of the plurality of trenches 50 passes through the base region 30 from the source region 20 so as to reach the drift region 10 and extends from the upper face of the source region 20, the upper face of the base region 30, and the upper face 10u of the drift region 10 toward the lower face 40d side of the drain region 40.

Here, the gate electrode 60 includes a first gate electrode 60f and a second gate electrode 60s. The second gate electrode 60s is provided on an opposite side of the first gate electrode 60f (see FIG. 11B). For example, the first gate electrode 60f is provided in a plurality of first trenches 50f via a first gate insulating film 61f, which passes through the base region 30, which is in contact with the first side face 20wf of the source region 20, from the source region 20 and extends up to the drift region 10 that is further in contact with the base region 30. In addition, the second gate electrode 60s is provided in a plurality of second trenches 50s via a second gate insulating film 61s, which passes through the base region 30, which is in contact with the second side face 20ws of the source region 20, from the source region 20 and extends up to the drift region 10 that is further in contact with the base region 30. The second side face 20ws is on an opposite side of the first side face 20wf of the source region 20.

In addition, the semiconductor device 2 includes second-conductivity type pillar areas 15 that extend from the base region 30 provided between a plurality of gate electrodes 60 (or a plurality of trenches 50) toward the drain region 40. In other words, the semiconductor device 2 includes a plurality of pillar areas 15 and a plurality of gate electrodes 60 in the direction Y that is perpendicular to direction X and direction Z. The pillar area 15 extends in a direction that is approximately parallel to the upper face 10u of the drain region 40. In a case where the base region 30 and the plurality of pillar areas 15 are viewed for direction Z, the base region 30 and the plurality of pillar areas 15 form like a comb shape.

Here, the pillar area 15 includes a first pillar area 15f of the second conductivity type and a second pillar area 15s of the second conductivity type. The second pillar area 15s is provided on an opposite side of the first pillar area 15f (see FIG. 11B). The first pillar area 15f extends from the base region 30 that is provided between the plurality of first gate electrodes 60f (or the plurality of first trenches 50f) toward the drift region 10 side on which the plurality of first gate electrodes 60f (or the plurality of first trenches 50f) extends. The second pillar area 15s extends from the base region 30 that is provided between the plurality of second gate electrodes 60s (or the plurality of second trenches 50s) toward the drift region 10 side on which the plurality of second gate electrodes 60s (or the plurality of second trenches 50s) extends.

In other words, the semiconductor device 2 has a super junction structure in which the drift region 10 of the first conductivity type and the pillar area 15 of the second conductivity type are alternately disposed in the direction Y.

In the semiconductor device 2, the width of the pillar area 15 in the direction Y is narrower than the width of the drift region 10 interposed between the pillar areas 15 in the Y direction. In addition, when the semiconductor device 2 is viewed for a direction (direction Z) perpendicular to the upper face 10u of the drift region 10, the thickness d (the thickness of the base region 30 in the direction X) of the base region 30 interposed between the source region 20 and the drift region 10, and the width L1 of the pillar area 15 in a direction (direction Y) that is approximately perpendicular to the extending direction (direction X) of the pillar area 15 from the base region 30 to the drift region 10 side satisfy the relation of L1≦2d.

In addition, the semiconductor device 2 includes a source electrode 70 (see FIGS. 2A and 2B) that is electrically connected to the source region 20 and the base region 30, and a drain electrode 81 that is electrically connected to the drain region 40.

The density of the impurity elements of the first conductivity type that are contained in the drift region 10 is lower than the density of the impurity elements of the first conductivity type that are contained in the drain region 40. The density of the impurity elements of the first conductivity type that are contained in the drift region 10, for example, is in the range of 1×10¹⁶ to 1×10¹⁷ (atoms/cm³). The density of the impurity elements of the first conductivity type that are contained in the drain region 40 is 1×10¹⁹ (atoms/cm³) or more.

The density of the impurity elements of the first conductivity type that are contained in the semiconductor region 16 is lower than that of the impurity elements of the first conductivity type that are contained in the drift region 10. The density of the impurity elements of the first conductivity type that are contained in the semiconductor region 16, for example, is 1×10¹⁶ or less (atoms/cm³).

The density of the impurity elements of the second conductivity type that are contained in the pillar areas 15 and the density of the impurity elements of the second conductivity type that are contained in the base region 30 are substantially the same. The density of the impurity elements that are contained in the pillar area 15 (or the density of the impurity elements that are contained in the base region 30), for example, is in the range of 5×10¹⁷ to 1×10¹⁸ (atoms/cm³).

The main component of each of the first drain region 40f and the second drain region 40s, for example, is silicon (Si).

The main component of the drain electrode 81, for example, is tungsten (W) or the like.

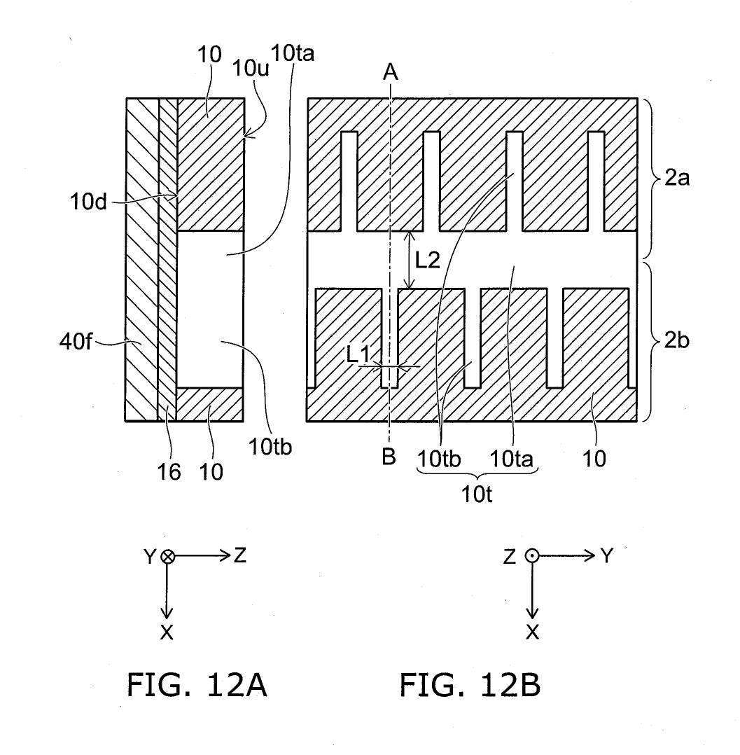

FIGS. 12A to 16B are schematic cross-sectional views and schematic top views illustrating processes of manufacturing the semiconductor device according to the second embodiment. FIGS. 12A, 13A, 14A, 15A, and 16A are schematic cross-sectional views along lines A-B illustrated in FIGS. 12B, 13B, 14B, 15B, and 16B as schematic top views.

First, a Si crystal substrate having a three-layer structure (a first drain region 40f/a semiconductor region 16/a drift region 10) is prepared previously in which a semiconductor region 16 and a drift region 10 are formed on a first drain region 40f in this order. Each of the three layers includes impurity elements of the first conductivity type.

Thereafter, as illustrated in FIGS. 12A and 12B, a trench 10ta and a plurality of trenches 10tb, which are connected to the trench 10ta, are formed in the drift region 10 that are formed from Si crystals by using the lithographic method and the RIE method. In other words, in the second embodiment, a trench 10ta and a plurality of trenches 10tb are formed within the drift region 10 that is provided previously on the first drain region 40f. In addition, before the trench 10ta and the plurality of trenches 10tb are formed inside the drift region 10, a semiconductor region 16 is provided between the first drain region 40f and the drift region 10. The impurity density of the semiconductor region 16 is lower than that of the impurities that are contained in the drift region 10.

In this stage, the trench 10ta (third trench) that extends in a direction (direction Y) that is approximately parallel to the upper face 10u of the drift region 10 and the plurality of trenches 10tb (fourth trenches) that extend in a direction (direction X) that is approximately perpendicular to the extending direction (direction Y) of the trench 10ta and the depth direction (direction Z) of the trench 10ta are formed. The plurality of trenches 10tb are connected to the trench 10ta. In addition, the trench 10ta and the plurality of trenches 10tb are collectively referred to as trenches 10t.

In FIGS. 12A and 12B, in a case where an upper area from the center of the trench 10ta is represented as area 2a, and a lower area from the center of the trench 10ta is represented as area 2b, there is an approximate phase shifting of 180° between the phases of the trench 10tb in area 2a and area 2b in the direction Y. In addition, the width L1 of the trench 10tb in the direction Y is smaller than the width L2 of the trench 10ta in the direction X.

Here, when viewed for a direction (direction Z) that is perpendicular to the upper face 10u of the drift region 10, the plurality of the trenches 10tb extends in a second direction (direction A in the figure) that is approximately perpendicular to a first direction (direction Y in the figure) in which the trench 10ta extends, and in a third direction (direction B in the figure). The third direction is approximately perpendicular to the direction Y and is opposite to the second direction. In addition, there is phase shifting between the phase in which a plurality of the trenches 10tb extending in the second direction is arranged in the first direction and the phase in which a plurality of the trenches 10tb extending in the third direction is arranged in the first direction. For example, the value of phase shifting is about 180°.

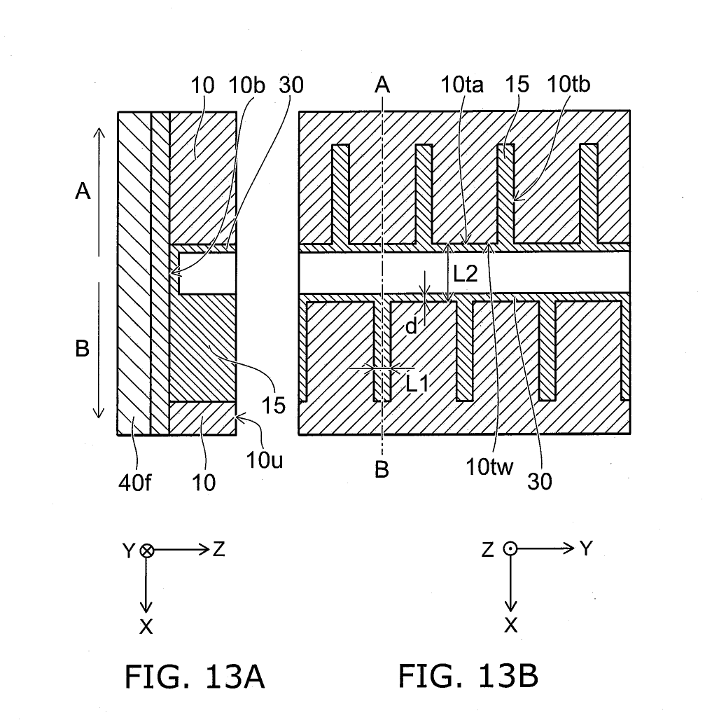

Next, as illustrated in FIGS. 13A and 13B, pillar areas 15 are formed inside the plurality of the trenches 10tb, and base regions 30 are formed on the inner side face 10tw of the trench 10ta and the bottom face 10b of the trench 10ta, using an epitaxial growth method. Here, while forming the pillar areas 15 and the base regions 30, impurity elements of the second conductivity type are introduced into the pillar areas 15 and the base regions 30. The trench 10ta is conditioned such that the base region 30 is not completely embedded in the trench 10ta.

In the second embodiment, when viewed for a direction (direction Z) that is perpendicular to the upper face 10u of the drift region 10, the width L1 of each of the plurality of the trenches 10tb in a direction that is approximately perpendicular to the extending direction of the plurality of the trenches 10tb and the thickness d of the base region 30 that is interposed between the source region 20 and the drift region 10 are adjusted so as to satisfy the following relation.

L1≦2×d Expression (1)

In addition, when viewed for the direction (direction Z) that is perpendicular to the upper face 10u of the drift region 10, the width L2 of the trench 10ta in a direction that is approximately perpendicular to the extending direction of the trench 10ta, the width L1 of each of the plurality of the trenches 10tb in a direction that is approximately perpendicular to the extending direction of the plurality of the trenches 10tb, and the thickness d of the base region 30 that is interposed between the source region 20 and the drift region 10 are adjusted so as to satisfy the following expression.

d≦L1<L2. Expression (2)

By designing the relation between the width L1 and the thickness d so as to satisfy Expression (1), the inside of the trench 10tb is completely embedded by the pillar area 15, but, by designing the relation between the width L1 and the width L2 so as to satisfy Expression (2), the inside of the trench 10ta is not completed embedded by the base region 30.

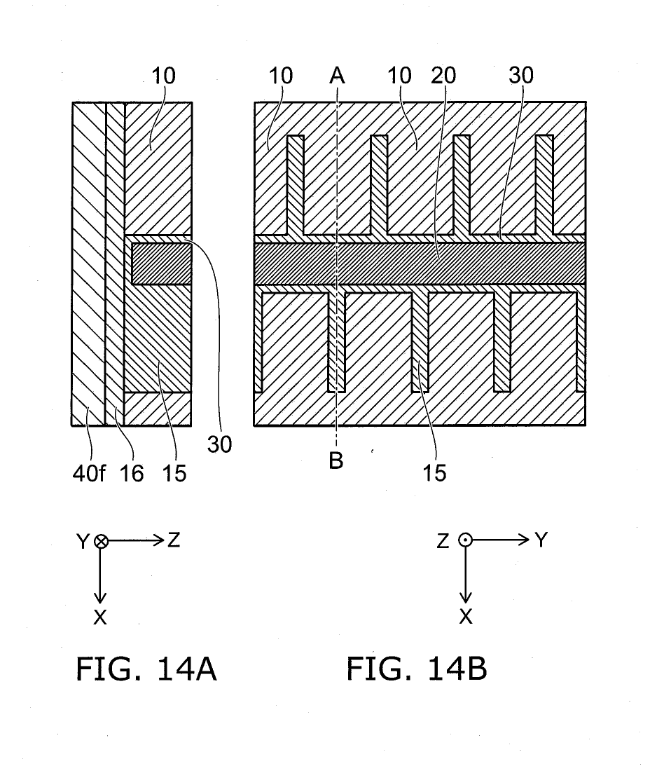

Next, as illustrated in FIGS. 14A and 14B, a source region 20 having side faces 20wf, 20ws and the bottom face 20d surrounded by the base region 30 is formed by an epitaxial growth method. While forming the source region 20, impurity elements of the first conductivity type are introduced into the source region 20. Next, as necessary, a CMP process is performed for the upper face of the drift region 10, the upper face of the base region 30, and the upper face of the source region 20 such that the upper face of the drain region 40, the upper face of the drift region 10, the upper face of the base region 30, and the upper face of the source region 20 are formed as one face.

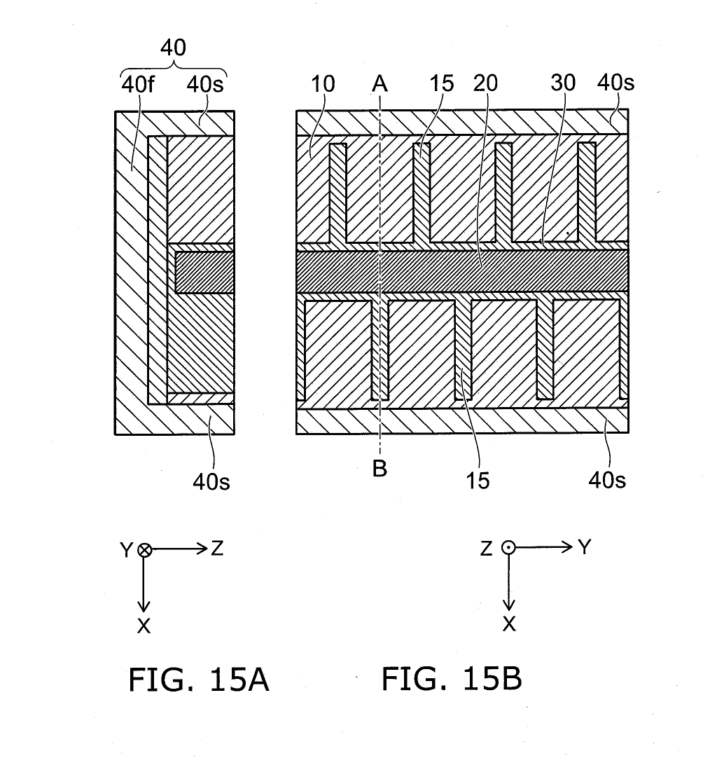

Next, as illustrated in FIGS. 15A and 15B, a second drain region 40s is formed such that the base region 30 and the drift region 10 are interposed between the source region 20 and the second drain region 40s. The second drain region 40s is formed so as to be in contact with the first drain region 40f. A trench that is used for forming the second drain region 40s in the drift region 10 previously is formed by the RIE (not illustrated in the figure), and the second drain region 40s is formed inside the trench by using the CVD method or the epitaxial growth method. The material of the second drain region 40s may be either polysilicon or a Si crystal.

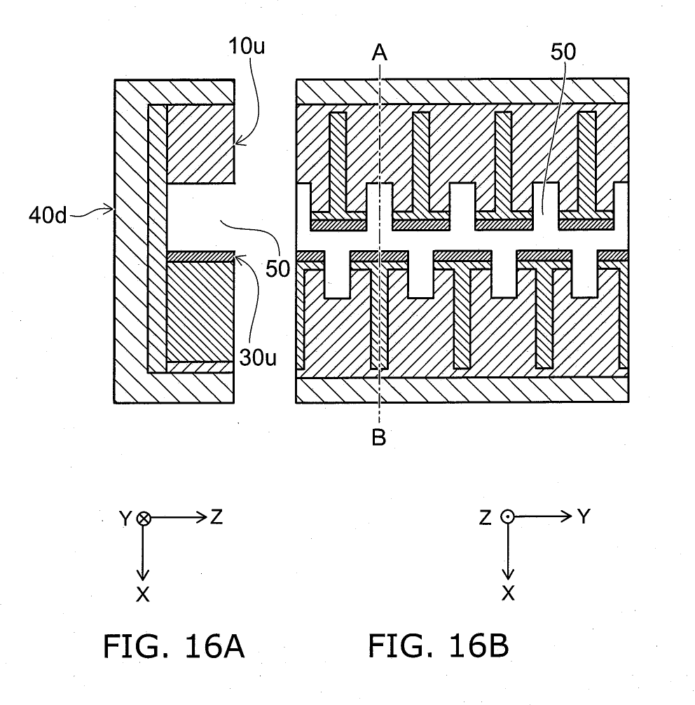

Next, as illustrated in FIGS. 16A and 16B, trenches 50 are formed by the RIE. The trenches 50 pass through the base region 30 from the source region 20 that is provided between the plurality of trenches 10tb, and reach the drift region 10. And the trenches 50 extend from the upper face 20u of the source region 20, the upper face 30u of the base region 30, and the upper face 10u of the drift region 10 toward the lower face 40d side of the drain region 40.

Thereafter, as illustrated in FIGS. 10, 11A, and 11B, a gate insulating film 61 is formed inside the trench 50, and a gate electrode 60 is formed further inside the trench 50 via the gate insulating film 61. The gate insulating film 61 and the gate electrode 60, for example, are formed by the CVD method. In addition, a source electrode 70 that is electrically connected to the source region 20 and the base region 30 and a drain electrode 81 that is electrically connected to the drain region 40 are formed.

After a trench that is used for forming the drain electrode 81 in the second drain region 40s previously is formed by the RIE (not illustrated in the figure), the drain electrode 81 is formed inside the trench by the CVD method. The semiconductor device 2 is formed by such a manufacturing process.

According to the semiconductor device 2 of the second embodiment, advantages same as those of the semiconductor device 1 of the first embodiment are acquired. In addition, in the semiconductor device 2 of the second embodiment, the semiconductor region 16 is provided between the first drain region 40f and the drift region 10. The impurity density of the semiconductor region 16 is lower than the impurity density of the drift region 10. Accordingly, the semiconductor region 16 serves as an electric field moderation layer. Therefore, the breakdown voltage of the semiconductor device 2 is further higher than the breakdown voltage of the semiconductor device 1.

According to the method of manufacturing the semiconductor device 2 of the second embodiment, advantages same as those of the semiconductor device 1 of the first embodiment are acquired. However, in the process of manufacturing the semiconductor device 2 of the second embodiment, the drift region 10 is prepared previously, and, after a plurality of the trenches 10tb is formed in the drift region 10, the pillar areas 15 of the plurality of the trenches 10tb are formed.

In other words, in the process of manufacturing the semiconductor device 2 of the second embodiment, the process of forming the extending portion 40e by processing the drain region 40, the process of forming the drift region 10 on the periphery of the extending portion 40e, and the process of diffusing the impurity elements of the drain region 40 into the drift region 10 by annealing the drain region 40 and the drift region 10, which are passed through in the first embodiment manufacturing the semiconductor device 1, are not necessary.

Accordingly, in the process of manufacturing the semiconductor device 2 of the second embodiment, the formation of the extremely fine extending portion 40e is not necessary, thereby less pattern collapse or less pattern deformation occurs during the manufacturing process. In other words, the process of manufacturing the semiconductor device 2 of the second embodiment becomes more effective as the narrowing of the MOSFET advances.

In addition, in the process of manufacturing the semiconductor device 2 of the second embodiment, unlike the first embodiment, it is not necessary to introduce impurity elements into the drift region 10 by diffusing the impurity elements of the drain region 40 into the drift region 10. Accordingly, in the semiconductor device 2 illustrated in FIGS. 10, 11A, and 11B, the distribution of the impurity density of the inside of the drift region 10 or the drain region 40 is more uniform than that of the semiconductor device 1. In other words, according to the second embodiment, a semiconductor device having higher reliability is formed.

### Variation of Second Embodiment

As described above, the impurity density of the semiconductor region 16 is lower than the impurity density of the drift region 10. However, in a case where the semiconductor region 16 is present below the drift region 10 and the pillar area 15, when the super junction structure is depleted, there is a possibility that the drift region 10 and the pillar area 15 are not sufficiently depleted due to the collapse of charge balance between the drift region 10 and the pillar area 15. In order to avoid this, the impurity density of the semiconductor region 16 and the impurity density of the drift region 10 may be configured to be the same by introducing impurity elements of the first conductivity type with injection of ions into the semiconductor region 16.

### Third Embodiment

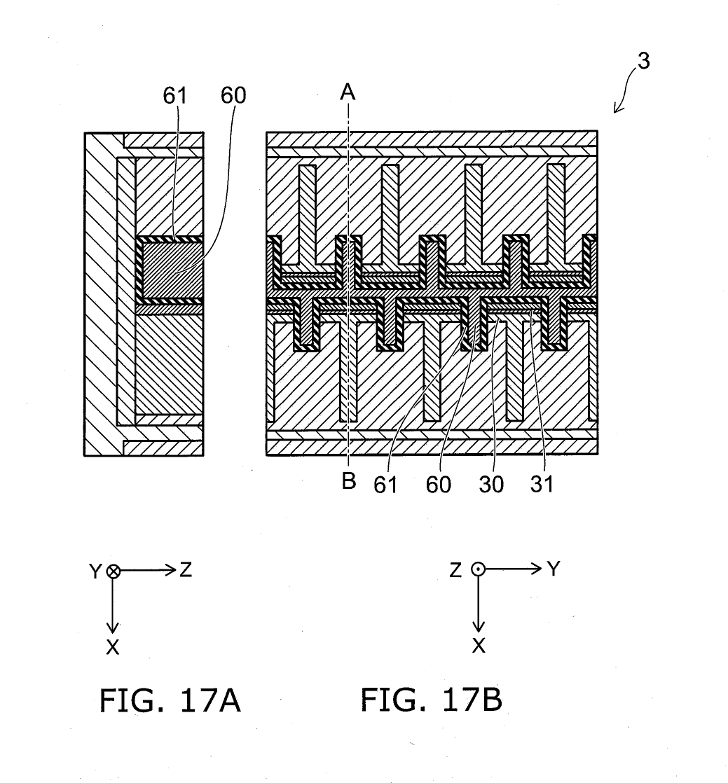

FIGS. 17A and 17B are schematic cross-sectional views and schematic top views of a semiconductor device according to a third embodiment.

FIG. 17A is a schematic cross-sectional view along line A-B illustrated in FIG. 17B as the schematic top views.

The semiconductor device 3 of the third embodiment is a MOSFET having a three-dimensional structure. The basic structure of the semiconductor device 3 is the same as the basic structure of the semiconductor device 2. However, the semiconductor device 3 further includes a base region 31 (sixth semiconductor region) of the second conductivity type between the base region 30 and the source region 20. The impurity density of the base region 31 is higher than the impurity density of the base region 30.

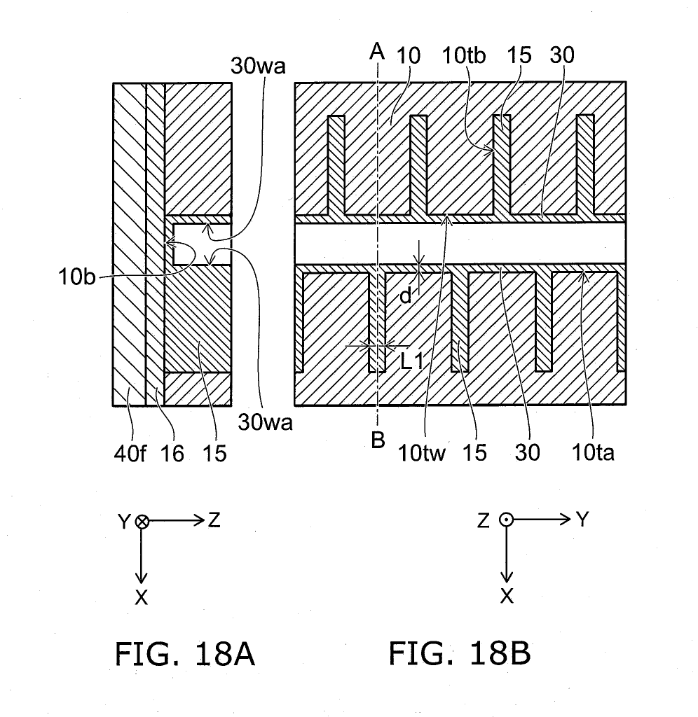

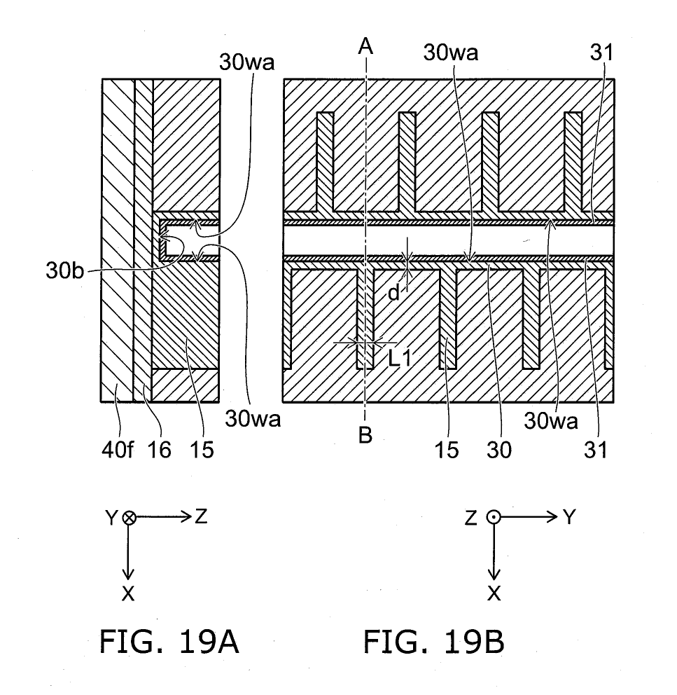

FIGS. 18A to 19B are schematic cross-sectional views and schematic top views illustrating processes of manufacturing the semiconductor device according to the third embodiment.

FIGS. 18A and 19A are the schematic cross-sectional views along lines A-B illustrated in FIGS. 18B and 19B as the schematic top views.

As illustrated in FIGS. 18A and 18B, pillar areas 15 are formed inside the plurality of the trenches 10tb, and base regions 30 are formed on the inner side face 10tw of the trench 10ta and the bottom face 10b of the trench 10ta, by an epitaxial growth method. The trench 10ta is conditioned such that the base region 30 is not completely embedded in the trench 10ta.

Next, after the base region 30 is formed, as illustrated in FIGS. 19A and 19B, a base region 31 is formed on the inner side face 30wa of the base region 30. Thereafter, as illustrated in FIGS. 17A and 17B, a source region 20, a gate electrode 60, a second drain region 40s, and a drain electrode 81 are formed.

According to the semiconductor device 3 of the third embodiment, advantages same as those of the semiconductor device 3 of the second embodiment are acquired. In addition, in the third embodiment, a base region 31 that has an impurity density higher than the density of impurities contained in the base region 30 is formed between the base region 30 and the source region 20.

In a semiconductor device having the super junction structure, it is notable that the depletion layer be sufficiently grown inside the drift region 10 and inside the pillar area 15 when the device is turned off. Accordingly, in a MOSFET having a two-dimensional structure, a structure is generally adopted such that the impurity density of the drift region 10 and the impurity density, of the pillar area 15 are approximately the same, and the width of the drift region 10 and the width of the pillar area 15 are approximately the same.

When there is an excessive difference between the impurity density of the drift region 10 and the impurity density of the pillar area 15, a phenomenon occurs in which a depletion layer grows in one of the drift region 10 and the pillar area 15, and a depletion layer does not grow in the other one of the drift region and the pillar area.

In the first embodiment, since the impurity density of the pillar area 15 is the same as that of the base region 30, the impurity density of the pillar area 15 is higher than the impurity density of the drift region 10. Accordingly, in the first embodiment, in order to promote the growth of the depletion layer inside the pillar area 15, the width L1 of the pillar area 15 is configured to be smaller than the width of the drift region 10 that is interposed between the pillar areas 15. Accordingly, a structure is formed in which the depletion layer sufficiently grows in each of the drift region 10 and the pillar area 15. However, in the first embodiment, since the pillar area 15 and the base region 30 are simultaneously formed, the design of the impurity density and the width of the pillar area 15 are determined by the impurity density of the base region of the MOSFET.

In contrast to this, in the third embodiment, the manufacturing process proceeds in which the process of forming the pillar area 15 and the base region 30 and the process of forming the base region 31 are separated from each other. In other words, since the impurity density of the base region 30 located on a further inner side than the base region 31 can be designed so as to be in accordance with the impurity density of the pillar area 15, the impurity density of the base region 31 can be designed in accordance with the impurity density of the base region of the MOSFET having the three-dimensional structure.

Accordingly, the impurity density and the width of the pillar area 15 can be freely designed in accordance with the impurity density and the width of the drift region 10 without a limitation by the impurity density of the base region of the MOSFET having the three-dimensional structure.

### Fourth Embodiment

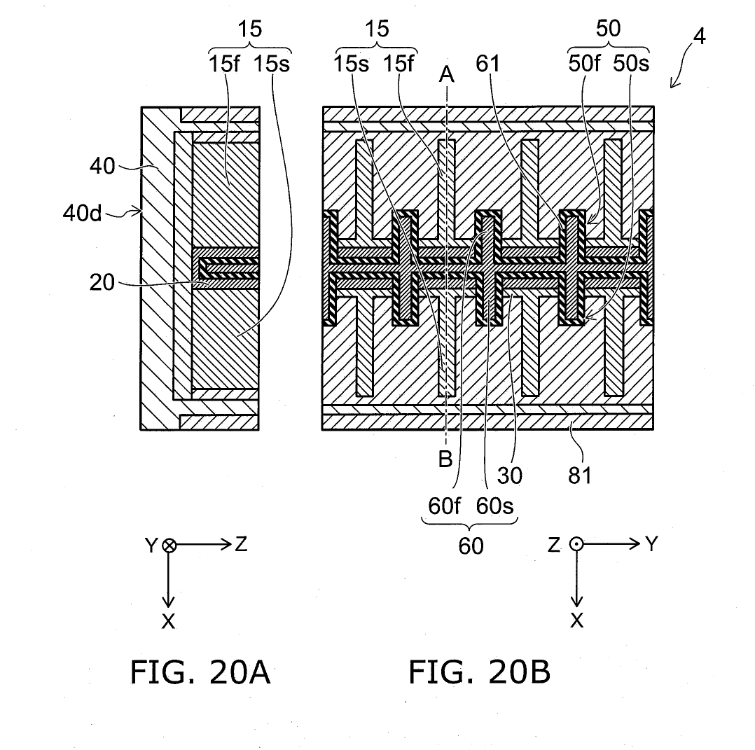

FIGS. 20A and 20B are schematic cross-sectional views and schematic top views of a semiconductor device according to a fourth embodiment.

FIG. 20A is a schematic cross-sectional view along line A-B illustrated in FIG. 20B as the schematic top view.

The basic structure of the semiconductor device 4 of the fourth embodiment is the same as the basic structure of the semiconductor device 2. However, in the semiconductor device 4, when the semiconductor device 4 is viewed for a direction (direction Z) that is perpendicular to the upper face 10u of the drift region 10, a plurality of the first gate electrodes 60f (or a plurality of the first trenches 50f) and a plurality of the second gate electrodes 60s (or a plurality of the second trenches 50s) are arranged in a direction (direction Y) in which the source region 20 extends. And the phase, in which the plurality of the first gate electrodes 60f (or the plurality of the first trenches 50f) is arranged in direction Y, and the phase, in which the plurality of the second gate electrodes 60s (or the plurality of the second trenches 50s) are arranged in direction Y, are in phase. In addition, the phase, in which the first pillar areas 15f provided between the plurality of the first gate electrodes 60f (or the plurality of the first trenches 50f) are arranged, and the phase, in which the second pillar areas 15s provided between the plurality of the second gate electrodes 60s (or the plurality of the second trenches 50s) are arranged, are in phase.

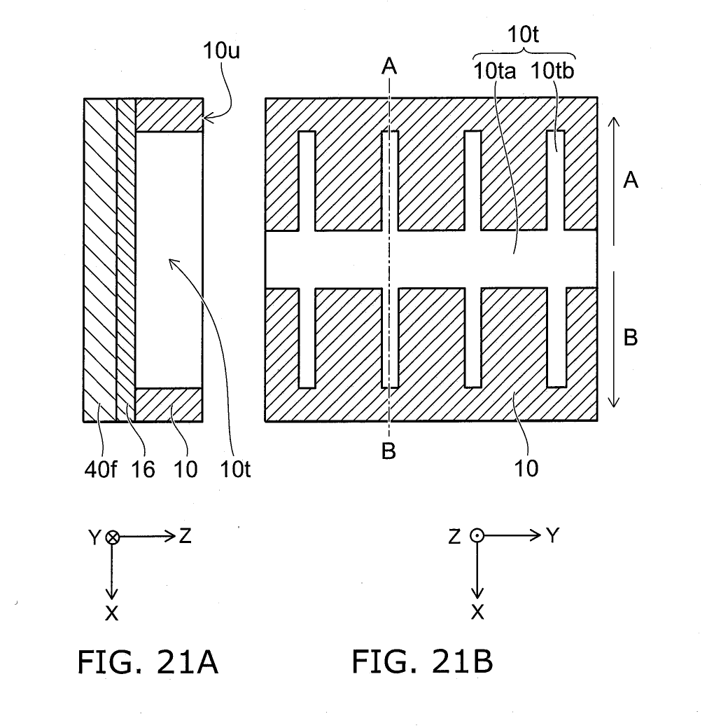

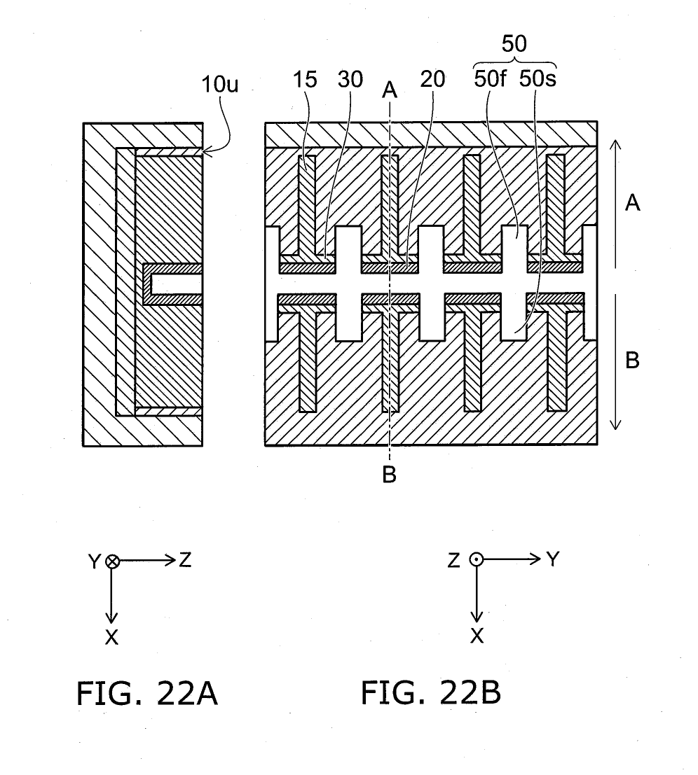

FIGS. 21A to 22B are schematic cross-sectional views and schematic top views illustrating processes of manufacturing the semiconductor device according to the fourth embodiment.

FIGS. 21A and 22A are the schematic cross-sectional views along lines A-B illustrated in FIGS. 21B and 22B as the schematic top views.

In the process of manufacturing the semiconductor device 4, for example, as illustrated in FIGS. 21A and 21B, when viewed for a direction that is perpendicular to the upper face 10u of the drift region 10, a plurality of trenches 10tb is formed in the drift region 10, which extends in a direction (direction A) that is approximately perpendicular to the direction (direction Y) in which the trench 10ta extends and direction B that is approximately perpendicular to direction Y and is opposite to direction A. Here, a phase in which the plurality of trenches 10tb, extending in direction A, is arranged in direction Y and a phase in which the plurality of trenches 10tb, extending in direction B, is arranged in direction Y are in phase.

Thereafter, according to the manufacturing method described above, pillar areas 15 are formed inside the trenches 10tb, and a base region 30 is formed inside the trench 10ta. Then, a source region 20 is formed further inside the base region 30.

Next, as illustrated in FIGS. 22A and 22B, trenches 50 (first trenches 50f and second trenches 50s) that are used for forming gate electrodes 60 are formed. In such a case, when viewed for a direction perpendicular to the upper face 10u of the drift region 10, a phase, in which a plurality of the first trenches 50f is arranged in direction Y, and a phase, in which a plurality of the second trenches 50s is arranged in direction Y, are in phase. Thereafter, according to the manufacturing method described above, gate electrodes 60 are formed inside the trenches 50 via the gate insulating film 61. The semiconductor device 4 and the manufacturing method thereof also belong to the embodiment.

### Fifth Embodiment

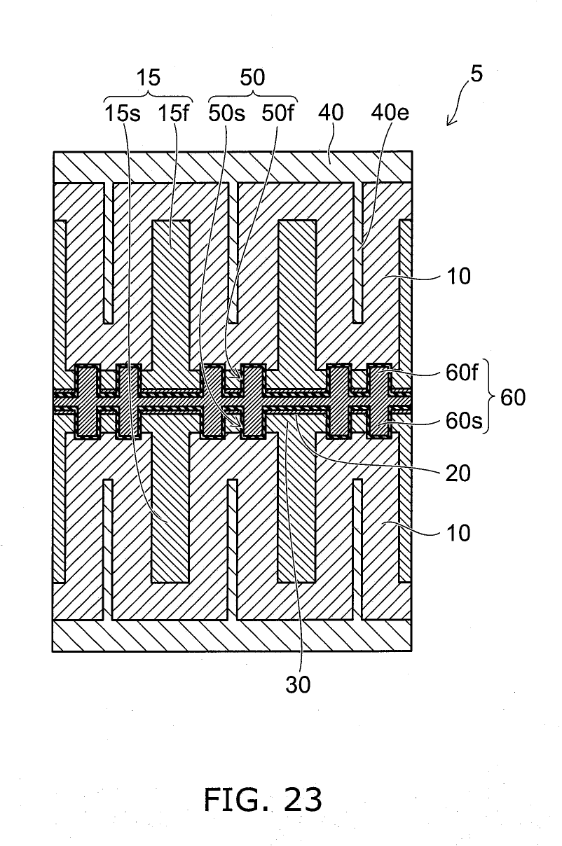

FIG. 23 is a schematic top view of a semiconductor device according to a fifth embodiment.

In the semiconductor device 5 of the fifth embodiment, a plurality of the first gate electrodes 60f (or a plurality of the first trenches 50f) and a plurality of the second gate electrodes 60s (or a plurality of the second trenches 50s) are arranged in a direction (direction Y) in which the source region 20 extends. And the phase, in which the plurality of the first gate electrodes 60f (or the plurality of the first trenches 50f) is arranged, and the phase, in which the plurality of the second gate electrodes 60s (or the plurality of the second trenches 50s) are arranged, are in phase. In addition, the phase, in which the first pillar areas 15f provided between the plurality of the first gate electrodes 60f (or the plurality of the first trenches 50f) are arranged, and the phase, in which the second pillar areas 15s provided between the plurality of the second gate electrodes 60s (or the plurality of the second trenches 50s) are arranged, are in phase.

In addition, in the semiconductor device 5, a plurality of gate electrodes 60 is provided between the plurality of pillar areas 15. Accordingly, in the semiconductor device 5, the channel density further increases. Therefore, the on-resistance further decreases.

### Sixth Embodiment

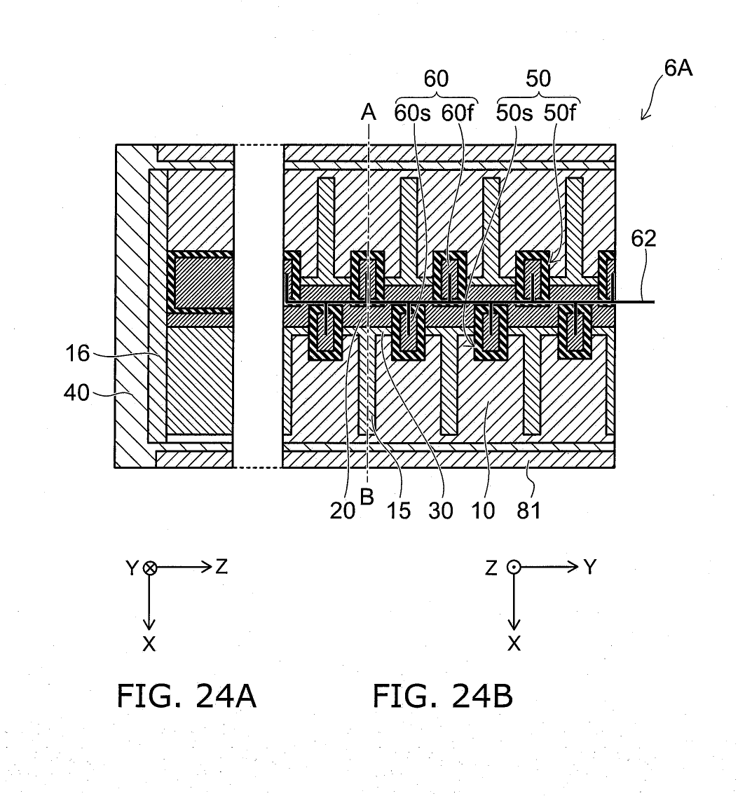

FIGS. 24A and 24B are schematic cross-sectional views and schematic top views of a semiconductor device according to a first example of a sixth embodiment.

FIG. 24A is a schematic cross-sectional view along line A-B illustrated in FIG. 24B as the schematic top view.

In the first to fifth embodiments described above, the gate electrodes 60 include a plurality of first gate electrodes 60f and a plurality of second gate electrodes 60s, and the plurality of first gate electrodes 60f and the plurality of second gate electrodes 60s are connected with each other inside the source region 20.

In the semiconductor device 6A of the first example of the sixth embodiment, a plurality of first gate electrodes 60f and a plurality of second gate electrodes 60s do are not connected with each other inside the source region 20, but the plurality of first gate electrodes 60f and the plurality of second gate electrodes 60s are electrically connected with each other through external wirings 62 (gate wirings 62). In the semiconductor device 6A, since the plurality of first gate electrodes 60f and the plurality of second gate electrodes 60s are disposed to be isolated from each other, the gate-to-source capacitance (Cgs) decreases. Accordingly, the operating speed of the semiconductor device 6A further increases.

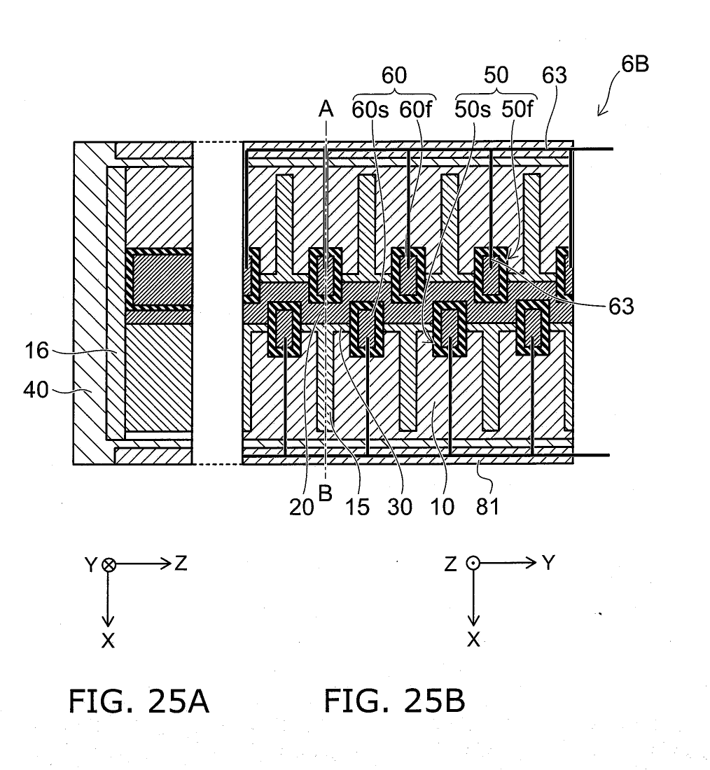

FIGS. 25A and 25B are schematic cross-sectional views and schematic top views of a semiconductor device according to a second example of the sixth embodiment.

FIG. 25A is a schematic cross-sectional view along line A-B illustrated in FIG. 25B as the schematic top view.

In the first example described above, although the external wirings 62 are disposed on the source region 20, the embodiment is not limited thereto. For example, in the semiconductor device 6B of the second example, the external wirings 63 (gate wirings 63) that are connected to the first gate electrode 60f and the second gate electrode 60s are drawn out on the drift region 10 and are drawn out further on the drain electrode 81. Such a form belongs to the embodiment.

According to the semiconductor device 6B, a structure is formed in which the gate wirings are not disposed on the source region 20 or inside the source region 20. Accordingly, the degree of freedom of the disposition of a source contact that can be in contact with the source region 20 or such a contact area can be increased, whereby contact resistance between the source region 20 and the source contact decreases. In addition, by drawing out the external wiring 63 up to the drain electrode 81, the width of the external wiring 63 can be increased. As a result, the wiring resistance Rg decreases. Furthermore, input capacitance (Ciss) due to parasitic capacitance between the external wiring 63 and the source region 20 decreases.

### Seventh Embodiment

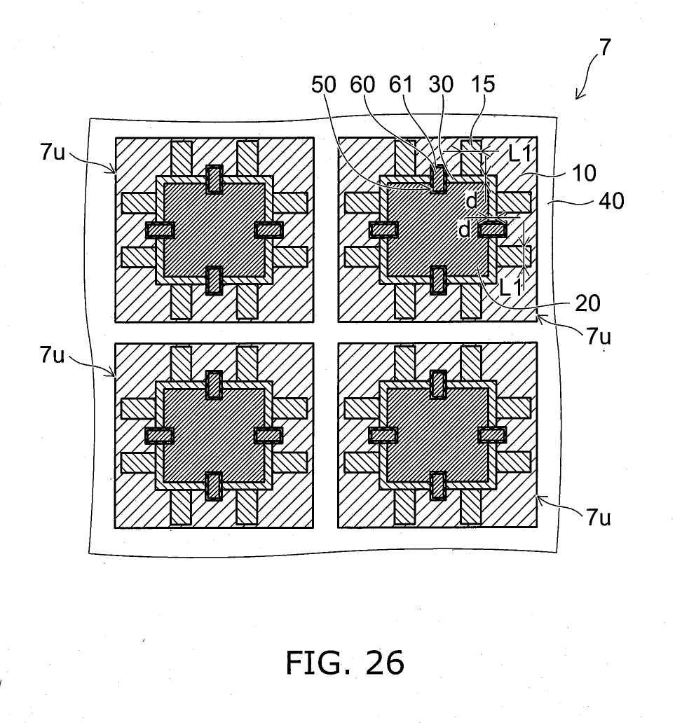

FIG. 26 is a schematic top view of a semiconductor device according to a seventh embodiment.

In the semiconductor device 7 of the seventh embodiment, the planar shape of a source region 20 is a quadrangle. In the semiconductor device 7, a base region 30 is provided on the outer periphery of the source region 20, a drift region 10 is provided on the outer periphery of the base region 30, and a drain region 40 is provided on the outer periphery of the drift region 10. The outer shape of the base region 30 and the outer shape of the drift region 10 are quadrangles.

In addition, in the semiconductor device 7, gate electrodes 60 are disposed on all sides of the source region 20 which is configured in the center of the semiconductor device. The gate electrodes 60 are provided inside a plurality of trenches 50 via gate insulating films 61. Each of the plurality of trenches 50 passes through the base region 30 from the source region 20 and reaches the drift region 10.

In the semiconductor device 7, by forming the source region 20, the base region 30, and the drift region 10 in quadrangles, a layout is formed in which basic units 7u in a quadrangle shape are arranged vertically and horizontally, the basic units 7u including the source region 20, the base region 30, and the drift region 10, respectively. In addition, the semiconductor device 7 includes each pillar area 15 of the second conductivity type that extends from the base region 30 provided between the plurality of trenches 50 toward the drift region 10 side.

In other words, the semiconductor device 7 has a super junction structure in which the drift region 10 of the first conductivity type and the pillar area 15 of the second conductivity type are alternately arranged on the outer periphery of the base region 30. In addition, the thickness d of the base region 30 that is interposed between the source region 20 and the drift region 10 and the width L1 of the pillar area 15 in a direction that is approximately perpendicular to the extending direction of the pillar area 15 from the base region 30 to the drift region 10 side satisfy the relation of L1≦2d.

In addition, the planar shapes of the source region 20, the base region 30, and the drift region 10 are not limited to quadrangles and may be a polygon having three or more angles.

### Eighth Embodiment

The Si crystal substrate having the three-layer structure (the first drain region 40f/the semiconductor region 16/the drift region 10) described in the second embodiment may be applied also to the process of manufacturing a MOSFET having a three-dimensional structure that includes a field plate electrode.

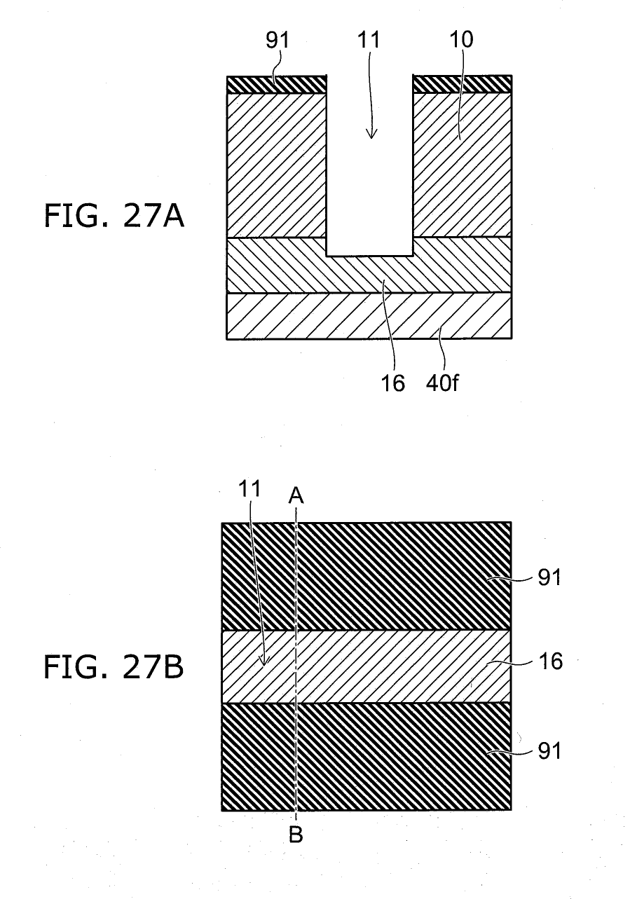

FIGS. 27A to 33B are schematic cross-sectional views and schematic top views illustrating processes of manufacturing a semiconductor device according to an eighth embodiment.

FIGS. 27A, 28A, 29A, 30A, 31A, 32A, and 33A are cross-sectional views along lines A-B illustrated in FIGS. 27B, 28B, 29B, 30B, 31B, 32B, and 33B as the schematic top views.

First, a Si crystal substrate having a three-layer structure (a first drain region 40f/a semiconductor region 16/a drift region 10) is prepared previously in which a semiconductor region 16 and a drift region 10 are formed on a first drain region 40f in the mentioned order.

Thereafter, as illustrated in FIGS. 27A and 27B, after a mask 91 is patterned by a lithographic method, a trench 11 is formed in a semiconductor region 16 that extends to the drift region 10 using the RIE method.

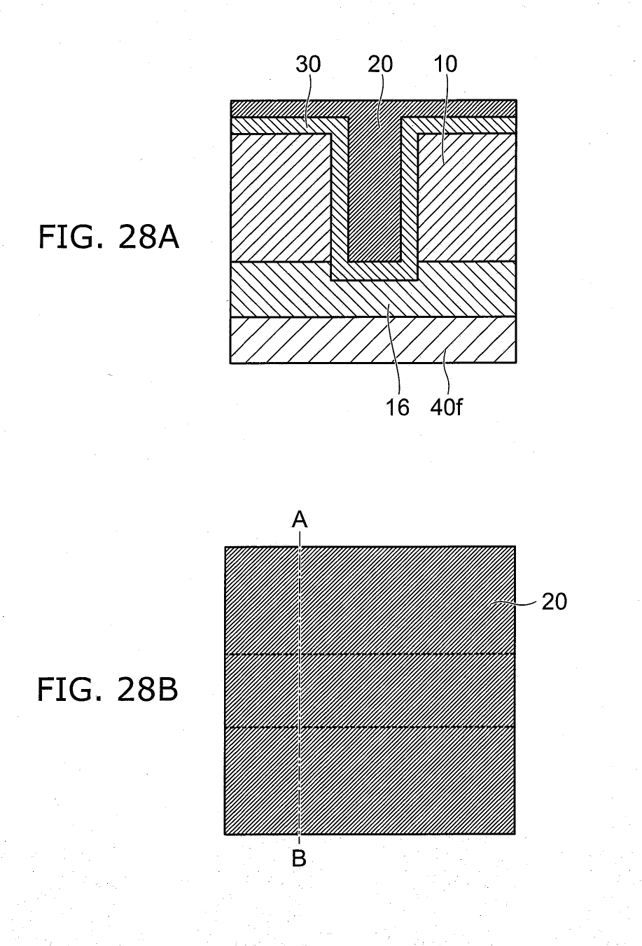

In addition, as illustrated in FIGS. 28A and 28B, a base region 30 is formed inside the trench 11 by using the epitaxial growth method. Here, while forming the base region 30, impurity elements of the second conductivity type are introduced into the base region 30. In addition, the trench 11 is conditioned so as not to completely embed the base region 30 in the trench 11.

Subsequently, a source region 20 is formed inside the base region 30. While forming the source region 20, impurity elements of the first conductivity type are introduced into the source region 20.

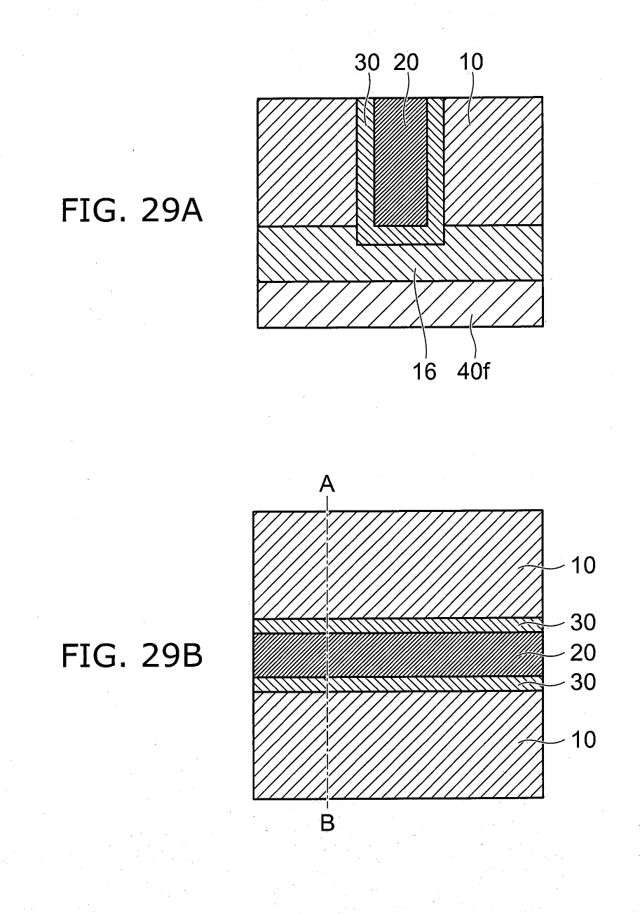

Next, as illustrated in FIGS. 29A and 29B, a CMP process is performed for the upper face of the drift region 10, the upper face of the base region 30, and the upper face of the source region 20 such that the upper face of the drain region 40, the upper face of the drift region 10, the upper face of the base region 30, and the upper face of the source region 20 are formed as one face.

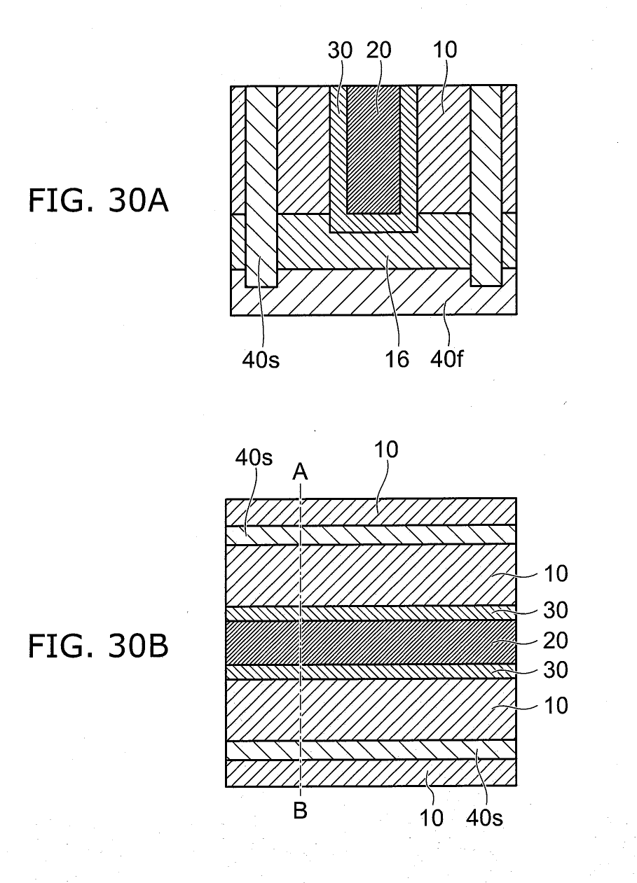

Next, as illustrated in FIGS. 30A and 30B, a second drain region 40s is formed such that the base region 30 and the drift region 10 are interposed between the source region 20 and the second drain region 40s. The second drain region 40s is formed so as to be in contact with the first drain region 40s. A trench that is used for forming the second drain region 40s in the drift region 10 previously is formed by the RIE (not illustrated in the figure), and the second drain region 40s is formed inside the trench using the CVD method or the epitaxial growth method. The material of the second drain region 40s may be either polysilicon or a Si crystal.

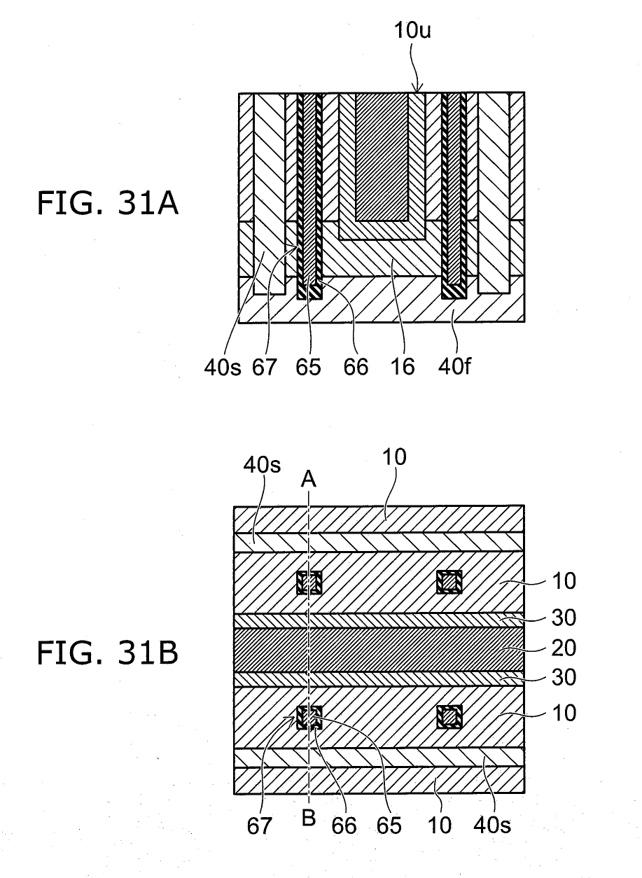

Next, as illustrated in FIGS. 31A and 31B, trenches 67 are formed in the drift region 10, the semiconductor region 16, and the first drain region 40f using the RIE. The trenches 67 reach up to the first drain region 40f from the upper face 10u of the drift region 10.

Subsequently, inside the trench 67, a field plate electrode 65 is formed via the plate insulating film 66 using the CVD. The material of the field plate electrode 65 is polysilicon.

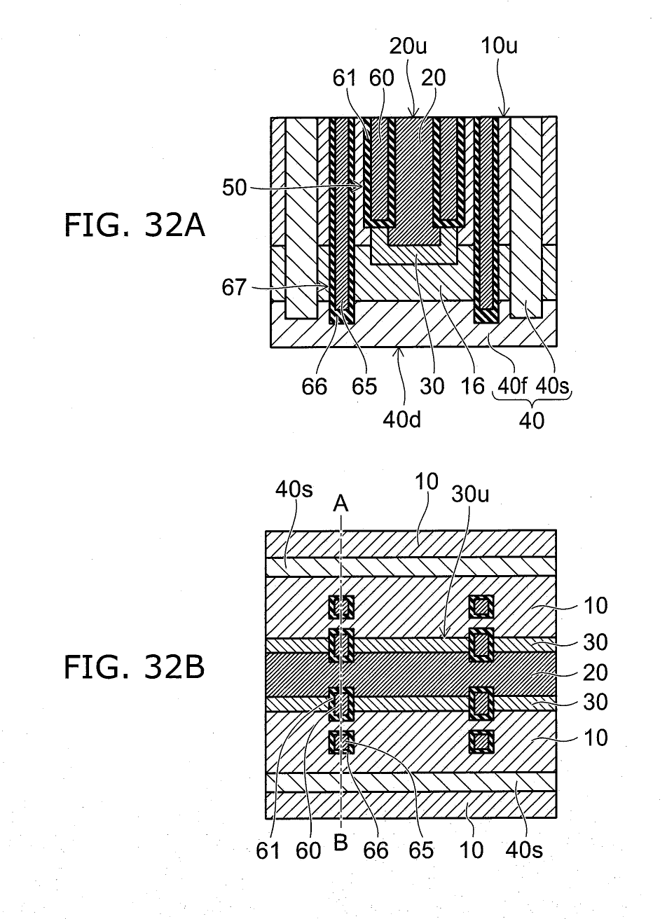

Next, as illustrated in FIGS. 32A and 32B, trenches 50 are formed using the RIE. The trenches 50 pass through the base region 30 from the source region 20 and reach the drift region 10, and the trenches 50 extend from the upper face 20u of the source region 20, the upper face 30u of the base region 30, and the upper face 10u of the drift region 10 toward the lower face 40d side of the drain region 40.

Thereafter, a gate insulating film 61 is formed inside the trench 50, and a gate electrode 60 is formed further inside the trench 50 via the gate insulating film 61. The gate insulating film 61 and the gate electrode 60, for example, are formed by the CVD method.

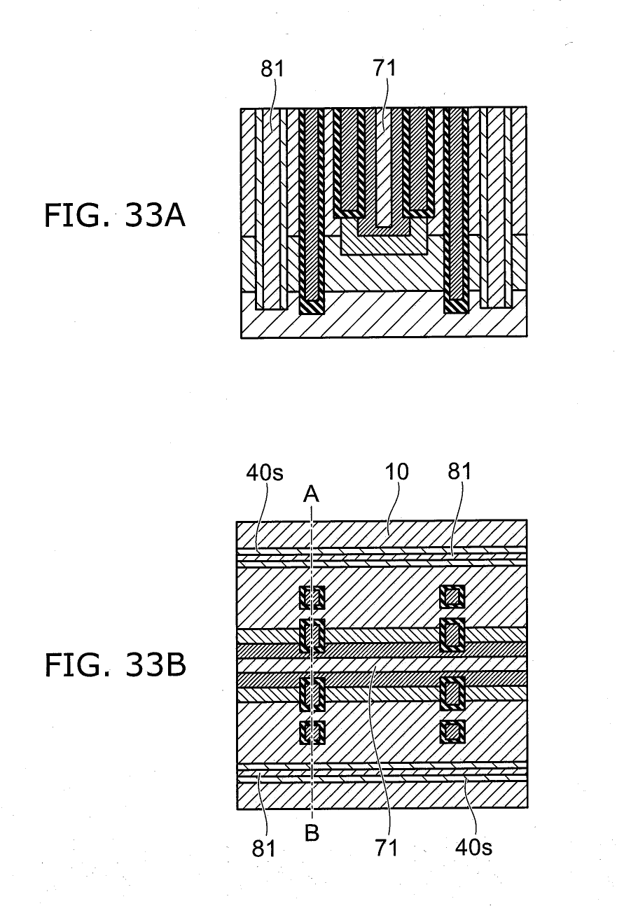

Next, as illustrated in FIGS. 33A and 33B, a source electrode 71 is formed inside the source region 20, and a drain electrode 81 is formed inside the second drain region 40s. Through such a manufacturing process, a MOSFET having a three-dimensional structure that includes the field plate electrode is formed.

As above, the embodiments have been described with reference to specific examples. However, the embodiments are not limited to such specific examples. In other words, these specific examples to which design changes are appropriately made by those skilled in the art shall be included in the scope of the embodiment as long as they include features of the embodiment. Each element, the disposition thereof, the material, the conditions, the shape, the size, and the like, which are included in each specific example described above are not limited to those that have been illustrated but may be appropriately changed.

In addition, the elements included in each embodiment described above can be combined as long as it is technically possible, and a combination thereof contains the scope of the embodiment, as long as it includes the features of the embodiment. Furthermore, in the scope of the concept of the embodiment, various variations or modifications may be considered by those skilled in the art, and it is understood that such variations and modifications belong to the scope of the embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a first semiconductor region of a first conductivity type;
a second semiconductor region of the first conductivity type having a side face and a lower face, and the side face and the lower face surrounded by the first semiconductor region;
a third semiconductor region of a second conductivity type provided between the second semiconductor region and the first semiconductor region;
a fourth semiconductor region of the first conductivity type being in contact with an outer side face of the first semiconductor region, the outer side face opposite to an inner side face of the first semiconductor region, and the inner side face being in contact with the third semiconductor region;
a plurality of first electrodes being in contact with the second semiconductor region, the third semiconductor region, and the first semiconductor region via an insulating film;
a plurality of pillar areas of the second conductivity type extending from the third semiconductor region toward the fourth semiconductor region, each of the plurality of pillar areas being provided between adjacent ones of the plurality of first electrodes, and extending in a direction parallel to an upper face of the first semiconductor region;
a second electrode electrically connected to the second semiconductor region and the third semiconductor region; and
a third electrode electrically connected to the fourth semiconductor region,
an impurity density of each of the pillar areas and an impurity density of the third semiconductor region being substantially the same.

2. The device according to claim 1, wherein a thickness d of the third semiconductor region interposed between the second semiconductor region and the first semiconductor region and a width L1 of each of the pillar areas in a direction approximately perpendicular to an extending direction of the pillar areas satisfy relation of L1≦2×d.

3. The device according to claim 2, wherein the width L1 of the each of the pillar areas is smaller than a width of the first semiconductor region provided between adjacent ones of the plurality of the pillar areas, and the plurality of the pillar areas extend from the third semiconductor region to the first semiconductor region side.

4. The device according to claim 1, wherein the fourth semiconductor region is in contact with a lower face of the first semiconductor region in addition to being in contact with the outer side face of the first semiconductor region.

5. The device according to claim 4, further comprising:
a fifth semiconductor region of the first conductivity type between the lower face of the first semiconductor region and the fourth semiconductor region,
wherein a density of impurity elements contained in the fifth semiconductor region is lower than a density of impurity elements contained in the first semiconductor region.

6. The device according to claim 1, further comprising:
a sixth semiconductor region of the second conductivity type between the third semiconductor region and the second semiconductor region,
wherein an impurity density of the sixth semiconductor region is higher than the impurity density of the third semiconductor region.

7. The device according to claim 1,
wherein the plurality of first electrodes includes
first portions of the plurality of first electrodes extending from the second semiconductor region via the third semiconductor region to the first semiconductor region, the third semiconductor region being in contact with a first side face of the second semiconductor region, and the first semiconductor being in contact with the third semiconductor region; and
second portions of the plurality of first electrodes extending from the second semiconductor region via the third semiconductor region to the first semiconductor region, the third semiconductor region being in contact with a second side face of the second semiconductor region, the second side face being opposite to the first side face, and the first semiconductor being in contact with the third semiconductor region, and
the pillar areas include
first pillar areas of the second conductivity type extending from the third semiconductor region provided between adjacent ones of first portions of the plurality of first electrodes toward the first semiconductor region side to which the first portions of the plurality of first electrodes extend; and
second pillar areas of the second conductivity type extending from the third semiconductor region provided between adjacent ones of second portions of the plurality of first electrodes toward the first semiconductor region side to which the second portions of the plurality of first electrodes extend.

8. The device according to claim 7,
wherein the first portions of the plurality of first electrodes and the second portions of the plurality of first electrodes are arranged in a direction in which the second semiconductor region extends, and
a phase in which each of the first portions of the plurality of first electrodes are arranged and a phase in which each of the second portions of the plurality of first electrodes are arranged are out-of-phase.

9. The device according to claim 7,
wherein the first portions of the plurality of first electrodes are arranged in a direction in which the second semiconductor region extends, and
a phase in which each of the first portions of the plurality of first electrodes are arranged and a phase in which each of the second portions of the plurality of first electrodes are arranged are in-phase.

10. The device according to claim 7, wherein a phase in which each of the first pillar areas provided between adjacent ones of first portions of the plurality of first electrodes are arranged and a phase in which each of the second pillar areas provided between adjacent ones of second portions of the plurality of first electrodes are arranged are out-of-phase.

11. The device according to claim 7, wherein a phase in which each of the first pillar areas provided between adjacent ones of first portions of the plurality of first electrodes are arranged and a phase in which each of the second pillar areas provided between adjacent ones of second portions of the plurality of first electrodes are arranged are in-phase.

12. A method of manufacturing a semiconductor device, the method comprising:
forming a third trench and a plurality of fourth trenches inside a first semiconductor region of a first conductivity type, the first semiconductor region provided on a fourth semiconductor region of the first conductivity type, the plurality of fourth trenches connecting to the third trench, the third trench extends in a direction approximately parallel to an upper face of the first semiconductor region, and the plurality of fourth trenches extend in a direction approximately perpendicular to a direction in which the third trench extends and a depth direction of the third trench;
forming pillar areas of a second conductivity type inside the plurality of fourth trenches and a third semiconductor region of the second conductivity type inside the third trench, and the third semiconductor region being not completely formed inside the third trench;
forming a second semiconductor region of the first conductivity type, and a side face and a lower face of the second semiconductor region being surrounded by the third semiconductor region;
forming a fifth trench passing through the third semiconductor region from the second semiconductor region between adjacent ones of the plurality of fourth trenches, the fifth trench reaching the first semiconductor region, and the fifth trench extending from an upper face of the second semiconductor region, an upper face of the third semiconductor region, and the upper face of the first semiconductor region to a lower face side of the fourth semiconductor region;
forming a first electrode via an insulating film inside the fifth trench; and
forming a second electrode electrically connected to the second semiconductor region and the third semiconductor region, and forming a third electrode electrically connected to the fourth semiconductor region.

13. The method according to claim 12, before the forming of the third trench and the plurality of fourth trenches inside the first semiconductor region, the method further comprising:
forming a fifth trench extending in a direction approximately parallel to an upper face of the fourth semiconductor region and a plurality of sixth trenches connecting to the fifth trench inside the fourth semiconductor region, and the plurality of sixth trenches extending in a direction approximately perpendicular to a direction in which the fifth trench extends and a depth direction of the fifth trench;
forming the first semiconductor region inside the fifth trench and inside the plurality of sixth trenches, the first semiconductor region being not completely embedded inside the fifth trench and the plurality of sixth trenches; and
annealing the fourth semiconductor region and the first semiconductor region.

14. The method according to claim 12, wherein the third trench and the plurality of fourth trenches are formed inside the first semiconductor region previously formed on the fourth semiconductor region.

15. The method according to claim 12, wherein a width L1 of each of the plurality of fourth trenches in a direction approximately perpendicular to a direction in which the plurality of fourth trenches extend and a thickness d of the third semiconductor region interposed between the second semiconductor region and the first semiconductor region are adjusted to satisfy relation of L1≦2×d.

16. The method according to claim 12, wherein a width L2 of the third trench in a direction approximately perpendicular to a direction in which the third trench extends, a width L1 of each of the plurality of fourth trenches in a direction approximately perpendicular to a direction in which the plurality of fourth trenches extend, and a thickness d of the third semiconductor region interposed between the second semiconductor region and the first semiconductor region are adjusted to satisfy relation of d≦L1<L2.

17. The method according to claim 12, wherein, before the forming of the third trench and the plurality of fourth trenches inside the first semiconductor region, a fifth semiconductor region is provided between the fourth semiconductor region and the first semiconductor region, and the fifth semiconductor region has an impurity density lower than a density of impurities contained in the first semiconductor region

18. The method according to claim 12, after the forming of the third semiconductor region, the method further comprising forming a sixth semiconductor region of the second conductive type on an inner side face of the third semiconductor region, and the sixth semiconductor region has an impurity density higher than a density of impurities contained in the third semiconductor region.

19. The method according to claim 12,
wherein the plurality of fourth trenches extend in a second direction approximately perpendicular to a first direction in which the third trench extends and extend in a third direction approximately perpendicular to the first direction, and the third direction being opposite to the second direction, and
a phase in which the plurality of fourth trenches extending in the second direction are arranged in the first direction and a phase in which the plurality of fourth trenches extending in the third direction are arranged in the first direction are out-of-phase.

20. The method according to claim 12,
wherein the plurality of fourth trenches extend in a second direction approximately perpendicular to a first direction in which the third trench extends and extend in a third direction approximately perpendicular to the first direction, and the third direction being opposite to the second direction, and
a phase in which the plurality of fourth trenches extending in the second direction are arranged in the first direction and a phase in which the plurality of fourth trenches extending in the third direction are arranged in the first direction are in-phase.
